(19) United States
(12) Patent Application Publication
(10) Pub. No.: US 2025/0027971 A1
(43) Pub. Date: Jan. 23, 2025

(54) Physical Quantity Sensor, Physical Quantity Sensor Device, And Inertial Measurement Unit

(71) Applicant: SEIKO EPSON CORPORATION, Tokyo (JP)

(72) Inventor: Satoru TANAKA, Chino (JP)

(21) Appl. No.: 18/910,383

(22) Filed: Oct. 9, 2024

Related U.S. Application Data
(62) Division of application No. 17/455,071, filed on Nov. 16, 2021.

(30) Foreign Application Priority Data
Nov. 17, 2020 (JP) 2020-190614

(51) Int. Cl. G01P 15/125; G01P 15/08

(52) U.S. Cl. CPC G01P 15/125; G01P 2015/0831

(57) ABSTRACT

A physical quantity sensor includes a substrate, first and second electrodes, and a movable body having a first mass and a torque generator. A first to n-th regions having a first to n-th ends are provided at the first mass. A first straight line having a smallest angle with an X axis passes through two ends of the first to n-th ends. A second straight line extends along the first electrode. A first normal line with the first electrode intersects with a proximal end of the first electrode. A second normal line with the first electrode intersects with a distal end of the first electrode. The first and second straight lines do not intersect with each other in a region between the first normal line and the second normal line. The first and second straight lines and the second normal line pass through the torque generator.

This application is a divisional application of U.S. patent application Ser. No. 17/455,071 filed Nov. 16, 2021, which is based on, and claims priority from JP Application Serial Number 2020-190614, filed Nov. 17, 2020, the disclosures of which are hereby incorporated by reference herein in their entireties.

### BACKGROUND

### 1. Technical Field

The present disclosure relates to a physical quantity sensor, a physical quantity sensor device, an inertial measurement unit, and the like.

### 2. Related Art

In the related art, a physical quantity sensor that detects a physical quantity such as acceleration is known. As such a physical quantity sensor, for example, a seesaw type acceleration sensor that detects acceleration in a Z-axis direction is known. For example, JP-T-2008-529001 discloses an acceleration sensor that implements high sensitivity by forming a plurality of inter-electrode gaps by providing a step on a back surface side of a movable body. JP-A-2013-040856 discloses an acceleration sensor that implements high sensitivity by forming a plurality of inter-electrode gaps by providing a step in a detector on a substrate. JP-A-2019-045172 discloses an acceleration sensor in which sticking of a movable body to a substrate is prevented by providing a stopper on a substrate side.

In JP-T-2008-529001, since stoppers are provided on both the movable body and the substrate, an inter-electrode gap distance is conversely increased, and it is difficult to achieve the high sensitivity. In JP-A-2013-040856, an electrode or a wiring provided on a surface of the substrate may be disconnected at a step of the substrate. In JP-A-2019-045172, since the stopper is provided on the substrate, the inter-electrode gap distance between the movable body and a fixed electrode of the substrate increases, and thus it is difficult to achieve the high sensitivity. As described above, the structures in JP-T-2008-529001, JP-A-2013-040856, and JP-A-2019-045172 have a problem in that it is difficult to implement both high sensitivity and prevention of sticking.

### SUMMARY

An aspect of the present disclosure relates to a physical quantity sensor including: a substrate on which a first fixed electrode is provided, the first fixed electrode being orthogonal to a Z axis when three axes orthogonal to one another are an X axis, a Y axis, and a Z axis; and a movable body including a first mass portion facing the first fixed electrode in a Z-axis direction along the Z axis, and provided to be swingable with respect to the substrate about a rotation axis along the Y axis. The movable body includes a first surface that is a surface on a substrate side, and a second surface that is a surface on a back side with respect to the first surface. On the first surface of the first mass portion, a first region to an n-th region, n being an integer equal to or greater than 2, are provided so as to face the first fixed electrode with a gap therebetween, a step is provided between adjacent regions, and the first region to the n-th region are disposed in order from a closest region to the rotation axis. Ends of the first region to the n-th region on a side far from the rotation axis are set as a first end to an n-th end. In a cross-sectional view from the Y-axis direction along the Y axis, in a state where the movable body is maximally displaced around the rotation axis, when a virtual straight line having a smallest angle with the X axis among virtual straight lines passing through two ends of the first end to the n-th end is set as a first virtual straight line, a straight line along a main surface of the first fixed electrode is set as a second virtual straight line, a straight line intersecting with an end of the first fixed electrode closest to the rotation axis and extending along the Z axis is set as a first normal line, and a straight line intersecting with an end of the first fixed electrode farthest from the rotation axis and extending along the Z axis is set as a second normal line, the first virtual straight line and the second virtual straight line do not intersect with each other in a region between the first normal line and the second normal line.

Another aspect of the present disclosure relates to a physical quantity sensor device including the physical quantity sensor described above and an electronic component electrically coupled to the physical quantity sensor.

Another aspect of the present disclosure relates to an inertial measurement unit including the physical quantity sensor described above and a controller that performs control based on a detection signal output from the physical quantity sensor.

### BRIEF DESCRIPTION OF THE DRAWINGS

FIG. 1 is a plan view of a physical quantity sensor according to a first embodiment.

FIG. 2 is a cross-sectional view taken along line A-A of FIG. 1.

FIG. 3 is a cross-sectional view taken along line B-B of FIG. 1.

FIG. 4 is a cross-sectional view taken along line C-C of FIG. 1.

FIG. 5 is an illustrative diagram of the physical quantity sensor according to the first embodiment.

FIG. 6 is an example of a case where a first virtual straight line and a second virtual straight line intersect with each other.

FIG. 7 is a modification of a method of forming a step.

FIG. 8 is an illustrative diagram of a physical quantity sensor according to a second embodiment.

FIG. 9 is an example of a case where a first virtual straight line and a second virtual straight line intersect with each other.

FIG. 10 is a plan view of a physical quantity sensor according to a third embodiment.

FIG. 11 is a cross-sectional view of the physical quantity sensor according to the third embodiment.

FIG. 12 is a plan view of a physical quantity sensor according to a fourth embodiment.

FIG. 13 is a cross-sectional view of the physical quantity sensor according to the fourth embodiment.

FIG. 14 is a perspective view of the physical quantity sensor according to the fourth embodiment.

FIG. 15 is a graph showing a relationship between a hole size of a through hole and damping.

FIG. 16 is a graph showing a relationship between the hole size of the through hole and the damping.

FIG. 17 is a graph showing a relationship between the hole size of the through hole and the damping.

FIG. 18 is a graph showing a relationship between a normalized through hole thickness and normalized damping.

FIG. 19 shows a configuration example of a physical quantity sensor device.

FIG. 20 is an exploded perspective view showing a schematic configuration of an inertial measurement unit including the physical quantity sensor.

FIG. 21 is a perspective view of a circuit board of the physical quantity sensor.

### DESCRIPTION OF EXEMPLARY EMBODIMENTS

Hereinafter, the present embodiment will be described. Embodiments described below do not unduly limit the scope of the claims. All of the configurations described in the present embodiment are not necessarily essential constituent elements. In the following drawings, some components may be omitted for convenience of description. In each of the drawings, for ease of understanding, a dimensional ratio of each component is different from the actual dimensional ratio.

### 1. First Embodiment

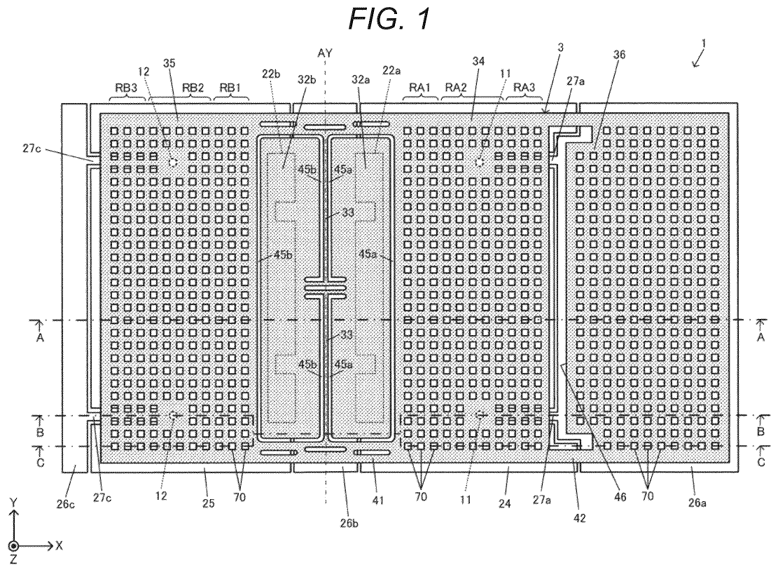

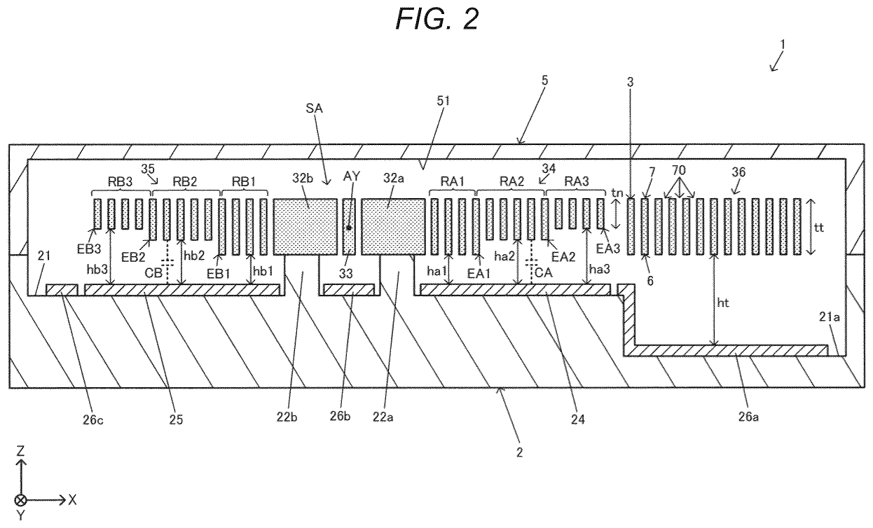

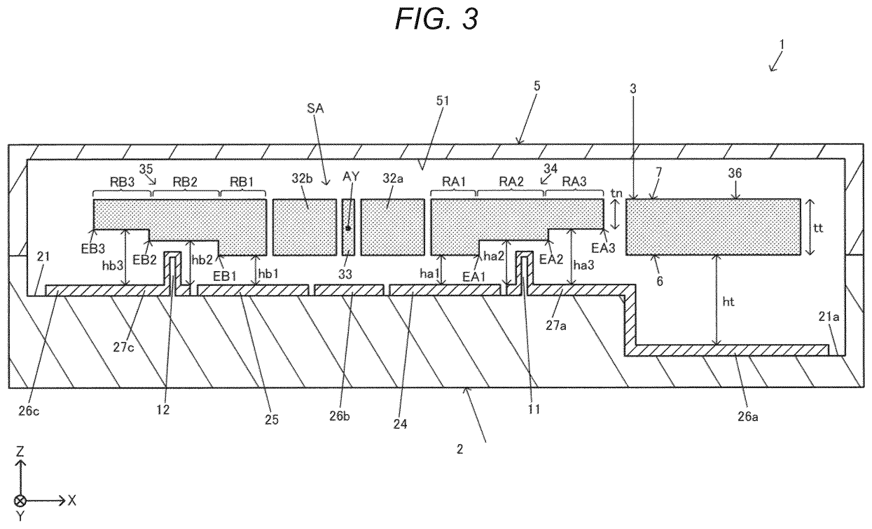

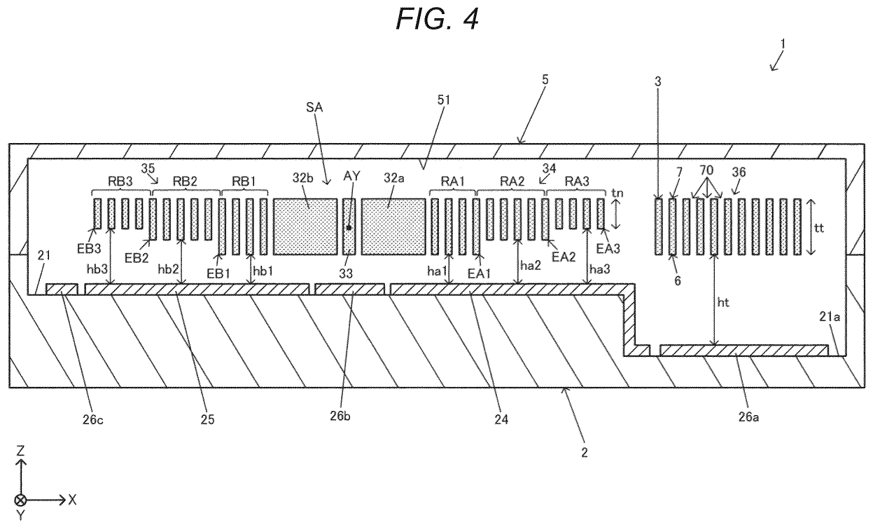

First, a physical quantity sensor 1 according to a first embodiment will be described with reference to FIGS. 1, 2, 3, and 4 by taking an acceleration sensor that detects acceleration in a vertical direction as an example. FIG. 1 is a plan view of the physical quantity sensor 1 according to the first embodiment. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. The physical quantity sensor 1 is a micro electro mechanical systems (MEMS) device, and is, for example, an inertial sensor. In FIG. 1, for convenience of description of an internal configuration of the physical quantity sensor 1, illustration of a substrate 2, a lid 5, and the like shown in FIGS. 2 to 4 is omitted. In FIGS. 1 to 4, for convenience of description, a dimension of each member, an interval among members, and the like are schematically shown. For example, a thickness, a gap distance, and the like of the movable body 3 are actually very small. In the following description, a case where the physical quantity detected by the physical quantity sensor 1 is acceleration will be mainly described as an example, whereas the physical quantity is not limited to the acceleration, and may be other physical quantities such as angular velocity, speed, pressure, displacement, and gravity. The physical quantity sensor 1 may be used as a gyro sensor, a pressure sensor, a MEMS switch, or the like. For convenience of description, an X axis, a Y axis, and a Z axis are shown in each figure as three axes orthogonal to each other. A direction along the X axis is referred to as an “x-axis direction”. A direction along the Y axis is referred to as a “Y-axis direction”. A direction along the Z axis is referred to as a “Z-axis direction”. Here, the X-axis direction, the Y-axis direction, and the Z-axis direction can also be referred to as a first direction, a second direction, and a third direction. An arrow tip side in each axial direction is also referred to as a “positive side”. A base end side is also referred to as a “negative side”. A positive side in the Z-axis direction is referred to as “upper”. A negative side in the Z-axis direction is referred to as “lower”. The Z-axis direction is along the vertical direction. An XY plane is along a horizontal plane. A term “orthogonal” includes not only the case of crossing at 90° but also the case of crossing at an angle slightly inclined from 90°.

The physical quantity sensor 1 shown in FIGS. 1 to 4 can detect the acceleration in the Z-axis direction which is the vertical direction. Such a physical quantity sensor 1 includes the substrate 2, the movable body 3 provided to face the substrate 2, and the lid 5 bonded to the substrate 2 and covering the movable body 3. The movable body 3 can also be referred to as a swing structure or a sensor element.

As shown in FIG. 1, the substrate 2 extends in the X-axis direction and the Y-axis direction, and has a thickness in the Z-axis direction. As shown in FIGS. 2 to 4, the substrate 2 is formed with a recess 21 and a recess 21a which are recessed toward a lower surface side and have different depths. The depth of the recess 21a from an upper surface is deeper than that of the recess 21. The recess 21 and the recess 21a include the movable body 3 therein and are formed to be larger than the movable body 3 in a plan view from the Z-axis direction. The recess 21 and the recess 21a function as a relief portion that prevents contact between the movable body 3 and the substrate 2. In the substrate 2, a first fixed electrode 24 and a second fixed electrode 25 are disposed on a bottom surface of the recess 21, and a dummy electrode 26a is disposed on a bottom surface of the recess 21a. The first fixed electrode 24 and the second fixed electrode 25 may be referred to as a first detection electrode and a second detection electrode. Dummy electrodes 26b and 26c are also disposed on the bottom surface of the recess 21. The first fixed electrode 24 and the second fixed electrode 25 are coupled to a QV amplifier, which is not shown, respectively, and detect an electrostatic capacitance difference as an electric signal by a differential detection method. Therefore, it is desirable that the first fixed electrode 24 and the second fixed electrode 25 have the same area. The movable body 3 is bonded to the upper surfaces of mount portions 22a and 22b of the substrate 2. Accordingly, the movable body 3 can be fixed to the substrate 2 in a state where the movable body 3 is separated from the bottom surface of the recess 21 of the substrate 2.

As the substrate 2, for example, a glass substrate made of a glass material containing alkali metal ions, for example, borosilicate glass such as glass of Pyrex (registered trademark) or Tempax (registered trademark) can be used. However, a constituent material of the substrate 2 is not particularly limited. For example, a silicon substrate, a quartz substrate, and a silicon on insulator (SOI) substrate may be used.

As shown in FIGS. 2 to 4, the lid 5 is formed with a recess 51 recessed toward the upper surface side. The lid 5 stores the movable body 3 in the recess 51 and is bonded to the upper surface of the substrate 2. A storage space SA for storing the movable body 3 is formed inside the lid 5 and the substrate 2. The storage space SA is an airtight space in which an inert gas such as nitrogen, helium, and argon is sealed. It is preferable that the storage space SA has a use temperature of about −40° C. to 125° C. and a substantially atmospheric pressure. However, an atmosphere of the storage space SA is not particularly limited, and may be, for example, a depressurized state or a pressurized state.

As the lid 5, for example, a silicon substrate can be used. However, the present disclosure is not particularly limited thereto. For example, a glass substrate or a quartz substrate may be used as the lid 5. As a method of bonding the substrate 2 and the lid 5, for example, anodic bonding, activation bonding, bonding using a bonding material such as glass frit, or the like can be used. However, the method is not particularly limited thereto, and may be appropriately selected depending on the material of the substrate 2 or the lid 5. The glass frit is also referred to as powder glass or low-melting glass.

The movable body 3 can be formed, for example, by etching a conductive silicon substrate doped with an impurity such as phosphorus (P), boron (B), or arsenic (As), particularly by a Bosch process which is a deep etching technique.

The movable body 3 is swingable around a rotation axis AY along the Y-axis direction. The movable body 3 includes fixing portions 32a and 32b, a support beam 33, a first mass portion 34, a second mass portion 35, and a torque generator 36. The torque generator 36 can also be referred to as a third mass portion. The fixing portions 32a and 32b, which are H-shaped central anchors, are bonded to the upper surfaces of the mount portions 22a and 22b of the substrate 2 by the anodic bonding or the like. The support beam 33 extends in the Y-axis direction, forms a rotation axis AY, and is used as a torsion spring. That is, when acceleration az acts on the physical quantity sensor 1, the movable body 3 swings about the rotation axis AY while twisting and deforming the support beam 33 with the support beam 33 as the rotation axis AY. The rotation axis AY can also be called a swing axis. The rotation of the movable body 3 about the rotation axis AY is a swing of the movable body 3 about the swing axis.

The movable body 3, which is a movable electrode, has a rectangular shape whose longitudinal direction is the X-axis direction in a plan view from the Z-axis direction. Then, the first mass portion 34 and the second mass portion 35 of the movable body 3 are disposed with the rotation axis AY along the Y-axis direction sandwiched therebetween in the plan view from the Z-axis direction. Specifically, in the movable body 3, the first mass portion 34 and the second mass portion 35 are connected by a first connector 41, and first openings 45a and 45b are provided between the first mass portion 34 and the second mass portion 35. The fixing portions 32a and 32b and the support beam 33 are disposed in the first openings 45a and 45b. In this way, by disposing the fixing portions 32a and 32b and the support beam 33 inside the movable body 3, it is possible to reduce the size of the movable body 3. The torque generator 36 is connected to the first mass portion 34 at both ends in the Y axis direction by a second connector 42. A second opening 46 is provided between the first mass portion 34 and the torque generator 36 in order to make the area of the first mass portion 34 equal to the area of the second mass portion 35. The first mass portion 34 and the torque generator 36 are located on the positive side in the X-axis direction with respect to the rotation axis AY. The second mass portion 35 is located on the negative side in the X-axis direction with respect to the rotation axis AY. The first mass portion 34 and the torque generator 36 are longer in the X-axis direction than the second mass portion 35, and a rotational moment around the rotation axis AY when the acceleration az in the Z-axis direction is applied is larger than that of the second mass portion 35.

When the acceleration az in the Z-axis direction is applied, the movable body 3 seesaw swings around the rotation axis AY due to a difference in the rotational moment. The seesaw swinging means that when the first mass portion 34 is displaced to the positive side in the Z-axis direction, the second mass portion 35 is displaced to the negative side in the Z-axis direction. Conversely, when the first mass portion 34 is displaced to the negative side in the Z-axis direction, the second mass portion 35 is displaced to the positive side in the Z-axis direction.

In the movable body 3, the first connector 41 and the fixing portions 32a and 32b arranged in the Y-axis direction are coupled to each other by the support beam 33 extending in the Y-axis direction. Therefore, the movable body 3 can be displaced by the seesaw swinging around the rotation axis AY with the support beam 33 as the rotation axis AY.

The movable body 3 has a through hole group 70 in the entire region thereof. By the through hole group, damping of air at the time of seesaw swinging of the movable body 3 is reduced, and the physical quantity sensor 1 can be appropriately operated in a wider frequency range.

Next, the first fixed electrode 24, the second fixed electrode 25, and the dummy electrodes 26a, 26b, and 26c disposed on the bottom surface of the recess 21 of the substrate 2 will be described.

As shown in FIG. 1, in the plan view from the Z-axis direction, the first fixed electrode 24 is disposed so as to overlap the first mass portion 34, and the second fixed electrode 25 is disposed so as to overlap the second mass portion 35. The first fixed electrode 24 and the second fixed electrode 25 are substantially symmetrically provided with respect to the rotation axis AY in the plan view from the Z-axis direction so that electrostatic capacitances Ca and Cb shown in FIG. 2 are equal to each other in a natural state in which the acceleration az in the Z-axis direction is not applied.

The first fixed electrode 24 and the second fixed electrode 25 are electrically coupled to a differential QV amplifier, which is not shown. When the physical quantity sensor 1 is driven, a drive signal is applied to the movable body 3. The electrostatic capacitance Ca is formed between the first mass portion 34 and the first fixed electrode 24. The electrostatic capacitance Cb is formed between the second mass portion 35 and the second fixed electrode 25. In the natural state in which the acceleration az in the Z-axis direction is not applied, the electrostatic capacitances Ca and Cb are substantially equal to each other.

When the acceleration az is applied to the physical quantity sensor 1, the movable body 3 seesaw swings about the rotation axis AY. By the seesaw swinging of the movable body 3, a separation distance between the first mass portion 34 and the first fixed electrode 24 and a separation distance between the second mass portion 35 and the second fixed electrode 25 change in opposite phases. Accordingly, the electrostatic capacitances Ca and Cb change in opposite phases. Accordingly, the physical quantity sensor 1 can detect the acceleration az based on the difference between capacitance values of the electrostatic capacitances Ca and Cb.

In order to prevent electrification drift due to substrate surface exposure and adhesion at the time of anodic bonding after forming the movable body, the dummy electrodes 26a, 26b, and 26c are provided on a glass exposed surface of the substrate 2 other than the first fixed electrode 24 and the second fixed electrode 25. The dummy electrode 26a is located on the positive side in the X-axis direction with respect to the first fixed electrode 24, and is provided below the torque generator 36 so as to overlap the torque generator 36 in the plan view from the Z-axis direction. The dummy electrode 26b is provided below the support beam 33. The dummy electrode 26c is provided on a lower left side of the second mass portion 35. The dummy electrodes 26a, 26b, and 26c are electrically coupled by wiring, which is not shown. Accordingly, the dummy electrodes 26a, 26b, and 26c are set to the same potential. The dummy electrode 26b below the support beam 33 is electrically coupled to the movable body 3 which is a movable electrode. For example, a protrusion, which is not shown, is provided on the substrate 2, an electrode extending from the dummy electrode 26b is formed so as to cover a top of the protrusion, and the dummy electrode 26b is electrically coupled to the movable body 3 by the electrode coming into contact with the movable body 3. Accordingly, the dummy electrodes 26a, 26b, and 26c are set to the same potential as the movable body 3 which is the movable electrode.

As shown in FIG. 3, the physical quantity sensor 1 is provided with stoppers 11 and 12 for restricting the rotation of the movable body 3 about the rotation axis AY. That is, the stoppers 11 and 12 restrict the swing of the movable body 3. For example, when an excessive seesaw swinging occurs in the movable body 3, the tops of the stoppers 11 and 12 come into contact with the movable body 3, thereby restricting further seesaw swinging of the movable body 3. Details of the stoppers 11 and 12 will be described later.

As described above, the physical quantity sensor 1 according to the present embodiment includes the substrate 2 which is orthogonal to the Z axis and on which the first fixed electrode 24 is provided when three axes orthogonal to one another are the X axis, the Y axis, and the Z axis, and the movable body 3 which includes the first mass portion 34 facing the first fixed electrode 24 in the Z axis direction and is provided to be swingable with respect to the substrate 2 about the rotation axis AY along the Y axis. The movable body 3 includes a first surface 6 which is a surface on the substrate 2 side and a second surface 7 which is a surface on the back side with respect to the first surface 6. For example, when the positive side in the Z-axis direction is an upward direction and the negative side in the Z-axis direction is the downward direction, the first surface 6 is the lower surface of the movable body 3 and the second surface 7 is the upper surface of the movable body 3.

Further, as shown in FIGS. 2 to 4, the first surface 6 of the first mass portion 34 is provided with regions RA1 to RA3 which face the first fixed electrode 24 with a gap therebetween, are provided with a step between adjacent regions, and are disposed from the region RA1 to the region RA3 in the order of closeness to the rotation axis AY. The regions RA1, RA2, and RA3 are a first region, a second region, and a third region, respectively. Specifically, a step is provided between the regions on the first surface 6 such that the gap distance between the first mass portion 34 and the first fixed electrode 24 in each region increases from the region RA1 toward the region RA3. For example, as shown in FIGS. 2 to 4, when the gap distances in the regions RA1, RA2, and RA3 are respectively ha1, ha2, and ha3, a relationship of ha1<ha2<ha3 is established. As an example of the gap distance, for example, ha1 is about 1.3 μm, ha2 is about 1.8 μm, and ha3 is about 2.3 μm.

Similarly, the first surface 6 of the second mass portion 35 is provided with regions RB1 to RB3 which face the second fixed electrode 25 with a gap therebetween, are provided with a step between adjacent regions, and are disposed from the region RB1 to the region RB3 in the order of closeness to the rotation axis AY. Specifically, a step is provided between the regions on the first surface 6 such that the gap distance between the second mass portion 35 and the second fixed electrode 25 in each region increases from the region RB1 toward the region RB3. For example, as shown in FIGS. 2 to 4, when the gap distances in the regions RB1, RB2, and RB3 are respectively hb1, hb2, and hb3, a relationship of hb1<hb2<hb3 is established.

Although the number of regions is three in FIGS. 2 to 4, the number of regions may be two or four or more. That is, the first surface 6 of the first mass portion 34 is provided with regions RA1 to RAn which face the first fixed electrode 24 with a gap therebetween, are provided with a step between adjacent regions, and are disposed from the region RA1 to the region RAn in the order of closeness to the rotation axis AY. The region RA1 is the first region, and the region RAn is an n-th region. n is an integer of 2 or more. Specifically, a step is provided between the regions on the first surface 6 such that the gap distance between the first mass portion 34 and the first fixed electrode 24 in each region increases from the region RA1 toward the region RAn. For example, when i and j are integers satisfying 1≤i<j≤n, the gap distance between the first mass portion 34 and the first fixed electrode 24 in the region RAi is smaller than the gap distance in the region RAj. Similarly, the first surface 6 of the second mass portion 35 is provided with regions RB1 to RBn which face the second fixed electrode 25 with a gap therebetween, are provided with a step between adjacent regions, and are disposed from the region RB1 to the region RBn in the order of closeness to the rotation axis AY. Specifically, a step is provided between the regions on the first surface 6 such that the gap distance between the second mass portion 35 and the second fixed electrode 25 in each region increases from the region RB1 toward the region RBn. For example, the gap distance between the second mass portion 35 and the second fixed electrode 25 in the region RBi is smaller than the gap distance in the region RBj.

As described above, in the physical quantity sensor 1 according to the present embodiment, a plurality of inter-electrode gaps are formed by providing ends EA1 to EA3 and EB1 to EB3 which are steps on the first surface 6 which is the lower surface side of the movable body 3. In this way, it is possible to reduce the gap distances ha1 and hb1 in the regions RA1 and RB1 close to the rotation axis AY. Accordingly, it is possible to implement a narrow gap of the gap in the regions RA1 and RB1 close to the rotation axis AY, and thus it is possible to implement high sensitivity of the physical quantity sensor 1.

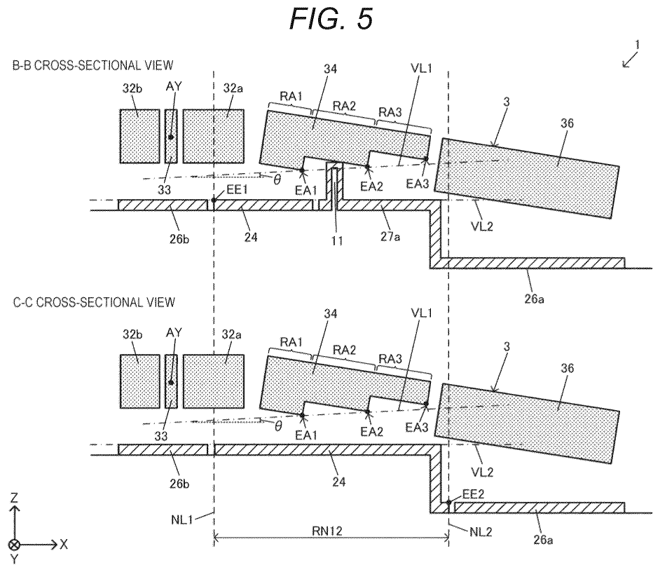

As described above, in the present embodiment, the high sensitivity is implemented by providing the step on the first surface 6 which is the lower surface side of the movable body 3. However, when the arrangement of the step or the like is not appropriate, a problem such as sticking in which the movable body 3 which is the movable electrode and the first fixed electrode 24 or the second fixed electrode 25 are stuck to each other occurs. Therefore, in the present embodiment, in order to prevent the occurrence of such a problem such as sticking, a method as described below is adopted. FIG. 5 is an illustrative diagram of a method according to the present embodiment. Hereinafter, a case where the method according to the present embodiment is applied to the first mass portion 34 will be mainly described as an example. The same method as in the case of the first mass portion 34 can be applied to the second mass portion 35, and thus a detailed description thereof will be omitted.

For example, ends of the regions RA1 to RAn on the side far from the rotation axis are referred to as ends EA1 to EAn. The regions RA1 to RAn are the first region to the n-th region. The ends EA1 to EAn are the first end to the n-th end. In the example of FIG. 5 in which n=3, the ends of the regions RA1 to RA3 on the side far from the rotation axis AY are referred to as ends EA1 to EA3. The ends EA1, EA2, and EA3 form a step between the regions.

In a cross-sectional 1 view from the Y-axis direction, in a state where the movable body 3 is maximally displaced around the rotation axis AY, among virtual straight lines passing through two ends among the ends EA1 to EAn, a virtual straight line having a smallest angle θ with respect to the X axis is set as a first virtual straight line VL1. Here, the virtual straight line passing through the two ends is, for example, a virtual straight line in contact with the two ends. For example, two ends are selected from among the ends EA1 to EAn, and the virtual straight line having the smallest angle θ with respect to the X axis among virtual straight lines passing through the selected two ends is set as the first virtual straight line VL1. In the example of FIG. 5 in which n=3, since the virtual straight line passing through the end EA1 and the end EA2 among the end EA1 to the end EA3 has the smallest angle θ with the X axis, the virtual straight line passing through the end EA1 and the end EA2 becomes the first virtual straight line VL1. The state in which the movable body 3 is maximally displaced about the rotation axis AY is, for example, a state in which the movable body 3 is displaced by swinging at a maximum angle about the rotation axis AY within a movable range of the movable body 3. Specifically, the maximum displacement state is a state in which the rotation of the movable body 3 is restricted by the stoppers 11 and 12. In FIG. 5, the virtual straight line passing through the end EA1 and the end EA2 is the first virtual straight line VL1 since the angle θ formed by the virtual straight line and the X axis is the smallest, whereas the present embodiment is not limited thereto. For example, a virtual straight line passing through the end EA2 and the end EA3 may be the first virtual straight line VL1, or a virtual straight line passing through the end EA1 and the end EA3 may be the first virtual straight line VL1. FIG. 5 is a schematic diagram for simplifying the description in the present embodiment, and the angle θ formed by the first virtual straight line VL1 and the X axis is actually smaller.

A straight line along a main surface of the first fixed electrode 24 is set as a second virtual straight line VL2. For example, in FIG. 5, the main surface of the first fixed electrode 24 is an upper surface which is a surface of the first fixed electrode 24 on the movable body 3 side, and a straight line along the upper surface is the second virtual straight line VL2. A straight line intersecting with an end EE1 of the first fixed electrode 24 closest to the rotation axis AY and extending along the Z axis is set as a first normal line NL1. A straight line intersecting with an end EE2 of the first fixed electrode 24 farthest from the rotation axis AY and extending along the Z axis is set as a second normal line NL2. For example, as shown in FIGS. 1 and 3, the end of the first fixed electrode 24 closest to the rotation axis AY is the end EE1 of the first fixed electrode 24 in FIG. 3 which is a cross-sectional view taken along line B-B of FIG. 1. As shown in FIGS. 1 and 4, the end of the first fixed electrode 24 farthest from the rotation axis AY is the end EE2 of the first fixed electrode 24 in FIG. 4, which is a cross-sectional view taken along line C-C of FIG. 1. Therefore, a straight line passing through the end EE1 of the first fixed electrode 24 closest to the rotation axis AY and extending along the Z axis is the first normal line NL1, and a straight line passing through the end EE2 of the first fixed electrode 24 farthest from the rotation axis AY and extending along the Z axis is the second normal line NL2.

In the present embodiment, as shown in FIG. 5, the first virtual straight line VL1 and the second virtual straight line VL2 do not intersect with each other in a region RN12 between the first normal line NL1 and the second normal line NL2. That is, the ends EA1, EA2, and EA3 which are steps on the lower surface of the movable body 3 are set such that the first virtual straight line VL1 and the second virtual straight line VL2 do not intersect with each other. In this way, since the first virtual straight line VL1 passing through the end EA1 and the end EA2 forming the step on the lower surface of the movable body 3 and the second virtual straight line VL2 along the main surface of the first fixed electrode 24 do not intersect in the region RN12 in the state where the movable body 3 is maximally displaced, sticking between the movable body 3 and the first fixed electrode 24 can be prevented. That is, the region RN12 is a region in a range between the end EE1 closest to the rotation axis AY and the end EE2 farthest from the rotation axis AY among the ends of the first fixed electrode 24. Therefore, in the region RN12, the fact that the first virtual straight line VL1 passing through the end EA1 and the end EA2 and the second virtual straight line VL2 along the main surface of the first fixed electrode 24 do not intersect with each other ensures that, even when the movable body 3 is maximally displaced around the rotation axis AY, the movable body 3 and the first fixed electrode 24 do not come into contact with each other and the movable body 3 and the first fixed electrode 24 do not approach each other at an extremely short distance. Therefore, it is possible to prevent the sticking between the movable body 3 and the first fixed electrode 24. Since the first virtual straight line VL1 and the second virtual straight line VL2 do not intersect with each other in the region RN12, the lower surface of the movable body 3 as a whole can be disposed close to the substrate 2 side while preventing the occurrence of sticking. Therefore, an average separation distance between the lower surface of the movable body 3 and the substrate 2 can be reduced, and the electrostatic capacitance Ca can be increased, so that the high sensitivity of the physical quantity sensor 1 can be implemented.

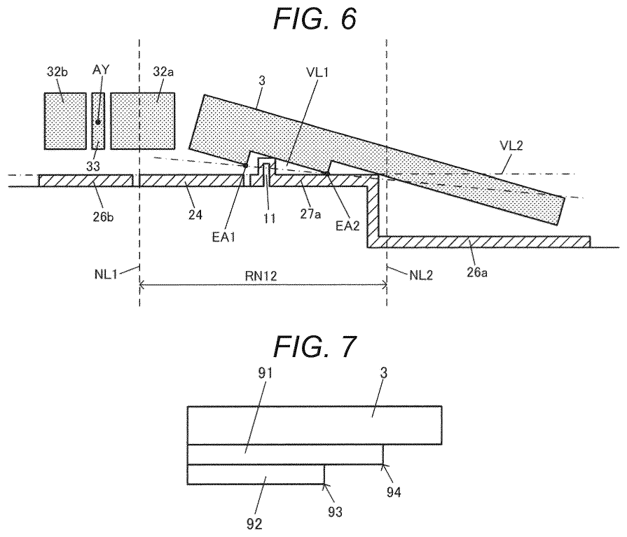

For example, FIG. 6 is an example in which the first virtual straight line VL1 and the second virtual straight line VL2 intersect each other in the region RN12. Here, for simplification of description, an example in which two ends EA1 and EA2 forming a step are provided on the lower surface of the movable body 3 is shown. As shown in FIG. 6, when the first virtual straight line VL1 and the second virtual straight line VL2 intersect with each other in the region RN12, for example, a problem occurs in which the end EA2 on the lower surface of the movable body 3 comes into contact with the first fixed electrode 24. If such a problem occurs, the physical quantity sensor 1 does not operate normally. In this regard, in the present embodiment, as shown in FIG. 5, even in the state where the movable body 3 is maximally displaced, the first virtual straight line VL1 and the second virtual straight line VL2 do not intersect with each other in the region RN12.

As described above, in the physical quantity sensor 1 according to the present embodiment, the ends EA1 to EA3 and EB1 to EB3 which are steps are provided on the first surface 6 which is the lower surface side of the movable body 3, thereby implementing the high sensitivity. Here, a reason why the gap distances ha1 and hb1 in the regions RA1 and RB1 close to the rotation axis AY are set to be small is that, compared with the regions RA3 and RB3 far from the rotation axis AY, the electrostatic capacitance can be increased by further narrowing the gap by utilizing the fact that the displacement in the Z-axis direction at the time of swinging of the movable body 3 is small and it is difficult for the movable body 3 to come into contact with the first fixed electrode 24 and the second fixed electrode 25, and the high sensitivity can be implemented. That is, the displacement of the movable body 3 in the Z-axis direction at the time of swinging is proportional to the distance from the rotation axis AY. Therefore, in the regions RA1 and RB1 close to the rotation axis AY, the displacement in the Z-axis direction with respect to the gap distances ha1 and hb1 at the time of swinging of the movable body 3 becomes small, and thus the movable body 3 hardly comes into contact with the first fixed electrode 24 and the second fixed electrode 25. Therefore, the gap between the first surface 6 of the region RA1 and the first fixed electrode 24 and the gap between the first surface 6 of the region RB1 and the second fixed electrode 25 can be narrowed. By narrowing the gap in the regions RA1 and RB1 in this way, the electrostatic capacitance can be increased, and the sensitivity of the physical quantity sensor 1 increases as the capacitance increases, so that high sensitivity can be implemented. By implementing high accuracy in this way, it is possible to implement low noise, and it is possible to provide the physical quantity sensor 1 with the high accuracy. On the other hand, by increasing the gap distances ha3 and hb3 in the regions RA3 and RB3 far from the rotation axis AY, the contact with the first fixed electrode 24 and the second fixed electrode 25 in the regions RA3 and RB3 can be prevented, and the movable range of the movable body 3 can be expanded.

For example, in JP-T-2008-529001 described above, a plurality of gaps having different gap distances are formed by providing the steps on the substrate side. However, since the electrodes and the wiring are provided on the steps on the substrate, disconnection or short circuit may be likely to occur as a process risk. In this regard, in the present embodiment, since the ends EA1 to EA3 and EB1 to EB3 serving as the steps are provided on the movable body 3 side to form the plurality of gaps having different gap distances, it is possible to prevent the occurrence of such problems such as the disconnection and the short circuit. Accordingly, a manufacturing process risk can be made very small, a yield can be improved, and cost of the physical quantity sensor 1 can be reduced.

Further, in the present embodiment, in the state where the movable body 3 is maximally displaced around the rotation axis AY, as shown in FIG. 5, the first virtual straight line VL1 and the second virtual straight line VL2 do not intersect with each other in the region RN12. In this way, by defining the step so that the movable body 3 does not come into contact with the first fixed electrode 24 or the like when the movable body 3 is maximally displaced, it is possible to prevent the sticking due to contact between the lower surface of the movable body 3 and the first fixed electrode 24 or the like while making full use of high sensitivity. That is, it is possible to implement both high sensitivity of the physical quantity sensor 1 and prevention of sticking, and it is possible to provide the physical quantity sensor 1 having high reliability over a long period of time.

In the present embodiment, the gap distance between the region RA1 to the region RAn of the first mass portion 34 and the first fixed electrode 24 increases in the order of the region RA1 which is the first region to the region RAn which is the n-th region. Similarly, the gap distance between the region RB1 to the region RBn of the second mass portion 35 and the second fixed electrode 25 increases in the order of the region RB1 to the region RBn. Taking FIGS. 2 to 4 as examples, the gap distances ha1, ha2, and ha3 in the regions RA1, RA2, and RA3 satisfy the relationship of ha1<ha2<ha3. Similarly, the gap distances hb1, hb2, and hb3 in the regions RB1, RB2, and RB3 satisfy the relationship of hb1<hb2<hb3.

By reducing the gap distances ha1 and hb1 in the regions RA1 and RB1 close to the rotation axis AY in this manner, it is possible to narrow the gap in the regions RA1 and RB1. Further, by narrowing the gap in the regions RA1 and RB1 in this way, the electrostatic capacitance can be increased, and the sensitivity of the physical quantity sensor 1 increases as the capacitance increases, so that the high sensitivity can be implemented. On the other hand, by increasing the gap distances ha3 and hb3 in the regions RA3 and RB3 far from the rotation axis AY, the contact with the first fixed electrode 24 and the second fixed electrode 25 in the regions RA3 and RB3 can be prevented, and the movable range of the movable body 3 can be expanded.

In FIGS. 1 to 5, the case where three regions RA1 to RA3 are provided as the regions RA1 to RAn with respect to the first mass portion 34 has been described, whereas the present embodiment is not limited thereto. The number of regions provided in the first mass portion 34 may be two, or may be four or more. That is, n=2 or n≥4 may be satisfied. The same applies to the regions RB1 to RBn provided in the second mass portion 35. For example, by increasing the number of regions, it is possible to obtain the same effect as in the case where a slope is provided on the lower surface of the first mass portion 34 or the second mass portion 35. That is, at each position between a position close to the rotation axis AY and a position far from the rotation axis AY, it is possible to make a change in the inter-electrode gap of the electrostatic capacitance more uniform, and it is possible to implement higher sensitivity.

The movable body 3 includes the torque generator 36 for generating rotational torque around the rotation axis AY. For example, the torque generator 36, which is the third mass portion, is provided on the positive side of the first mass portion 34 in the X-axis direction. A gap distance ht between the torque generator 36 and the substrate 2 is larger than the gap distance ha3 between the region RAn, which is the n-th region, and the first fixed electrode 24. Specifically, the gap distance ht is a separation distance between the torque generator 36 and the dummy electrode 26a formed on the substrate 2. For example, in FIGS. 2 to 4, the region RAn which is the n-th region is the region RA3, and the gap distance ht between the torque generator 36 and the substrate 2 is larger than the gap distance ha3 between the region RA3 and the first fixed electrode 24. The gap distance ht between the torque generator 36 and the substrate 2 is larger than the gap distance hb3 between the region RB3 and the second fixed electrode 25. For example, in FIGS. 2 to 4, the gap distance ht between the torque generator 36 and the substrate 2 is increased by forming the recess 21a having a height in the Z-axis direction lower than that of the recess 21 by deepening the substrate 2. Accordingly, it is possible to reduce damping, prevent sticking due to contact with the dummy electrode 26a, and expand the movable range of the movable body 3.

A thickness tt of the torque generator 36 in the Z-axis direction is larger than a thickness tn of the region RAn of the movable body 3 in the Z-axis direction. That is, as shown in FIGS. 2 to 4, the thickness tt of the torque generator 36 is larger than the thickness tn of the region RA3 which is the region RAn of the movable body 3. By increasing the thickness tt of the torque generator 36 in this way, it is possible to increase the mass of the torque generator 36 which is the third mass portion. Accordingly, the rotational torque of the torque generator 36 at the time of the seesaw swinging of the movable body 3 can be further increased, so that higher sensitivity can be implemented. By reducing the thickness tn of the movable body 3 in the region RA3 far from the rotation axis AY, the position of the lower surface in the region RA3 is located on the upper side, and the gap distance ha3 between the movable body 3 and the first fixed electrode 24 can be increased. Accordingly, the movable range of the movable body 3 can be expanded.

The thickness tt of the torque generator 36 may be larger than the thickness of the fixing portions 32a and 32b and the support beam 33. In this way, larger torque for rotating the movable body 3 can be generated, and higher sensitivity can be implemented.

In the physical quantity sensor 1 according to the present embodiment, the movable body 3 includes the second mass portion 35 which is provided to sandwich the rotation axis AY with respect to the first mass portion 34 in the plan view from the Z-axis direction. For example, the first mass portion 34 is disposed on the positive side in the X-axis direction from the rotation axis AY, and the second mass portion 35 is disposed on the negative side in the X-axis direction from the rotation axis AY. The first mass portion 34 and the second mass portion 35 are, for example, symmetrically disposed with respect to the rotation axis AY. The substrate 2 is provided with the second fixed electrode 25 facing the second mass portion 35. The first fixed electrode 24 and the second fixed electrode 25 are symmetrically disposed with respect to the rotation axis AY. The symmetry includes substantially symmetry.

In this manner, the first mass portion 34 and the second mass portion 35 are provided with the rotation axis AY sandwiched therebetween, and the first fixed electrode 24 facing the first mass portion 34 and the second fixed electrode 25 facing the second mass portion 35 are symmetrically disposed with respect to the rotation axis AY, so that the seesaw swing type physical quantity sensor 1 can be implemented. In a natural state in which the acceleration in the Z-axis direction is not applied, the electrostatic capacitances Ca and Cb in FIG. 2 can be made equal to each other. On the other hand, in a state where the movable body 3 is maximally displaced around the rotation axis AY, as shown in FIG. 5, the first virtual straight line VL1 and the second virtual straight line VL2 do not intersect with each other in the region RN12, so that it is possible to prevent the sticking while implementing the high sensitivity.

In the present embodiment, the same relationship as in FIG. 5 is established in the regions RB1, RB2, and RB3 of the second mass portion 35. For example, in the cross-sectional view from the Y-axis direction, in a state where the movable body 3 is maximally displaced around the rotation axis AY, among the virtual straight lines passing through two ends among the ends EB1 to EBn, a virtual straight line having the smallest angle with respect to the X axis is set as a third virtual straight line, and a straight line along the main surface of the second fixed electrode 25 is set as a fourth virtual straight line. A straight line which intersects with an end of the second fixed electrode 25 closest to the rotation axis AY and extends along the Z axis is set as a fifth normal line. A straight line which intersects with an end of the second fixed electrode 25 farthest from the rotation axis AY and extends along the Z axis is set as a sixth normal line. At this time, a relationship is established in which the third virtual straight line and the fourth virtual straight line do not intersect in the region between the fifth normal line and the sixth normal line.

As shown in FIG. 3, the physical quantity sensor 1 according to the present embodiment includes the stoppers 11 and 12 that restrict the rotation of the movable body 3 about the rotation axis AY. In FIG. 3, the stoppers 11 and 12 are implemented by protrusions provided on the substrate 2. The stopper may be implemented by an end of a step or the like instead of such a protrusion. When an excessive seesaw swinging occurs in the movable body 3, the tops of the stoppers 11 and 12 come into contact with the movable body 3, thereby restricting further seesaw swinging of the movable body 3. By providing such stoppers 11 and 12, it is possible to prevent excessive proximity between the movable body 3 having different potentials and the first fixed electrode 24 and the second fixed electrode 25. In general, since an electrostatic attractive force is generated between electrodes having different potentials, when the excessive proximity occurs, the electrostatic attractive force generated between the movable body 3 and the first fixed electrode 24 or the second fixed electrode 25 causes sticking in which the movable body 3 does not return to the first fixed electrode 24 or the second fixed electrode 25 while being attracted to the first fixed electrode 24 or the second fixed electrode 25. In such a state, since the physical quantity sensor 1 does not normally operate, the stoppers 11 and 12 are provided so that the excessive proximity does not occur.

Since the movable body 3 and the first fixed electrode 24 and the second fixed electrode 25 have different potentials, as shown in FIG. 3, electrodes 27a and 27c as protective films for preventing a short circuit are formed on the tops of the stoppers 11 and 12 so as to cover the tops. Specifically, as shown in FIGS. 1 and 3, the electrode 27a is drawn out from the dummy electrode 26a to the negative side in the X-axis direction, and the leading end of the drawn out electrode 27a is provided so as to cover the top of the stopper 11. An electrode 27c is drawn out from the dummy electrode 26c to the positive side in the X-axis direction, and the leading end of the drawn out electrode 27c is provided so as to cover the top of the stopper 12. Since the dummy electrodes 26a and 26c are set to the same potential as the movable body 3, even when the movable body 3 comes into contact with the electrodes 27a and 27c covering the tops of the stoppers 11 and 12, the short circuit is prevented.

Modifications such as providing an insulating layer made of silicon oxide, silicon nitride, or the like for preventing the short circuit or providing an electrode having a different potential at the tops of the stoppers 11 and 12 are also possible. Although the stoppers 11 and 12 are provided on the substrate 2 in FIG. 3, various modifications may be made such that the stopper for restricting the rotation of the movable body 3 about the rotation axis AY is provided on the movable body 3 or on the lid 5. For example, when the stopper is provided in the movable body 3, the dummy electrode may be provided in an area immediately below the stopper in the substrate 2.

The state in which the movable body 3 is maximally displaced about the rotation axis AY is, for example, a state in which the rotation of the movable body 3 is restricted by the stoppers 11 and 12. For example, in FIG. 5, the top of the stopper 11 comes into contact with the lower surface of the movable body 3, so that the rotation of the movable body 3 is restricted. The state in which the rotation of the movable body 3 is restricted by the stoppers 11 and 12 is a state in which the movable body 3 is maximally displaced around the rotation axis AY. In a state in which the rotation of the movable body 3 is restricted by the stoppers 11 and 12 as described above, in the present embodiment, as shown in FIG. 5, a condition that the first virtual straight line VL1 and the second virtual straight line VL2 do not intersect with each other in the region RN12 is established. Accordingly, it is possible to prevent the sticking while implementing the high sensitivity.

It is also possible to restrict the rotation of the movable body 3 about the rotation axis AY by a member or a structure other than the stoppers 11 and 12 which are protrusions provided on the substrate 2. In this case, the state in which the movable body 3 is maximally displaced about the rotation axis AY is a state in which the rotation of the movable body 3 is restricted by the member or structure.

The stoppers 11 and 12 have the same potential as the movable body 3. That is, as described above, the dummy electrode 26b provided below the support beam 33 is electrically coupled to the movable body 3 which is a movable electrode. The dummy electrodes 26a, 26b, and 26c are electrically coupled to each other by a wiring, which is not shown. Therefore, the dummy electrodes 26a, 26b, and 26c have the same potential as the movable body 3. On the other hand, as described with reference to FIG. 3, the electrodes 27a and 27c drawn out from the dummy electrodes 26a and 26c are formed on the tops of the stoppers 11 and 12 so as to cover the tops, and the stoppers 11 and 12 have the same potential as the dummy electrodes 26a, 26b, and 26c. Therefore, the stoppers 11 and 12 have the same potential as the movable body 3. Since the stoppers 11 and 12 and the movable body 3 have the same potential as described above, an unnecessary electrostatic force due to a different potential does not work, so that the sticking can be further prevented. Even when the tops of the stoppers 11 and 12 are in contact with the movable body 3 as shown in FIG. 5, the short circuit is prevented.

The physical quantity sensor 1 includes the dummy electrodes 26a, 26b, and 26c which are disposed in a region of the substrate 2 where the first fixed electrode 24 is not disposed and which faces the movable body 3 and have the same potential as the movable body 3. That is, as described above, since the dummy electrode 26b is electrically coupled to the movable body 3, and the dummy electrodes 26a, 26b, and 26c are electrically coupled by the wiring, which is not shown, the movable body 3 and the dummy electrodes 26a, 26b, and 26c have the same potential. As shown in FIGS. 2 to 4, the dummy electrodes 26a, 26b, and 26c are disposed in the region of the substrate 2 where the first fixed electrode 24 is not disposed and facing the movable body 3. More specifically, the dummy electrodes 26a, 26b, and 26c are disposed in a region of the substrate 2 where the first fixed electrode 24 and the second fixed electrode 25 are not disposed. In this manner, the dummy electrodes 26a, 26b, and 26c are disposed in the region where the first fixed electrode 24 and the second fixed electrode 25 are not disposed in the region facing the movable body 3. Accordingly, it is possible to prevent the exposure of the surface of the substrate 2. Therefore, it is possible to prevent the electrification drift due to the substrate surface exposure, sticking at the time of anodic bonding after forming the movable body, and the like. Since the dummy electrodes 26a, 26b, and 26c have the same potential as that of the movable body 3, the short circuit can be prevented even when the movable body 3 comes into contact with the dummy electrodes 26a, 26b, and 26c.

As shown in FIG. 1, the movable body 3 is provided with the through hole group 70 penetrating in the Z-axis direction. For example, in FIG. 1, the through hole group 70 including a plurality of square through holes is provided in the movable body 3. An opening shape of the through hole is not limited to a square, and may be a polygonal shape other than a square, or a circular shape. By providing the through hole group 70 in the movable body 3 in this manner, it is possible to reduce damping of air when the movable body 3 swings around the rotation axis AY. By reducing the damping, the physical quantity sensor 1 can be operated in a wider frequency range. Although an opening area of the through holes of the through hole group 70 is uniform in FIG. 1, it is desirable to make the opening area of the through holes larger in a region far from the rotation axis AY than in a region close to the rotation axis AY, as will be described later.

The gap distances ha1, ha2, and ha3 between the first mass portion 34 and the first fixed electrode 24 are, for example, 4.5 μm or less. That is, the relationship of ha1<ha2<ha3≤4.5 μm is established. More preferably, the gap distances ha1 and ha2 between the first mass portion 34 and the first fixed electrode 24 are preferably 4.1 μm or less. Similarly, the gap distances hb1, hb2, and hb3 between the second mass portion 35 and the second fixed electrode 25 are also, for example, 4.5 μm or less, and more preferably 4.1 μm or less. When the gap distance becomes sufficiently small in this way, the electrostatic capacitances Ca and Cb become sufficiently large, and the detection sensitivity of the physical quantity sensor 1 can be sufficiently increased. Further, even when the gap distance is made sufficiently small in this way, in the present embodiment, as described with reference to FIG. 5, the relationship that the first virtual straight line VL1 and the second virtual straight line VL2 do not intersect with each other in the region RN12 is established, and thus the occurrence of sticking can be prevented. Therefore, it is possible to provide the physical quantity sensor 1 capable of implementing both prevention of sticking and high sensitivity.

The angle θ between the first virtual straight line VL1 and the X axis is, for example, 0.7° or less. More preferably, the angle θ between the first virtual straight line VL1 and the X axis is, for example, 0.3° or less. For example, the second virtual straight line VL2 is a straight line along the X-axis direction, and the angle θ formed by the first virtual straight line VL1 and the X axis can also be referred to as an angle formed by the first virtual straight line VL1 and the second virtual straight line VL2.

For example, in the present embodiment, in a state where the movable body 3 is maximally displaced around the rotation axis AY, a virtual straight line having the smallest angle θ with respect to the X axis among virtual straight lines passing through two ends among the ends EA1 to EAn is set as the first virtual straight line VL1. The first virtual straight line VL1 can be said to be a straight line along the slope when the lower surface of the movable body 3 is regarded as the slope. In order to increase the sensitivity to the maximum while preventing the sticking, it is desirable that the first virtual straight line VL1 corresponding to the slope and the second virtual straight line VL2 along the main surface of the first fixed electrode 24 of the substrate 2 are as parallel to each other as possible in the state where the movable body 3 is maximally displaced. This is because, for example, when the first virtual straight line VL1 and the second virtual straight line VL2 become parallel to each other or are brought as parallel to each other as possible, the sensitivity of the physical quantity sensor 1 can be maximized by bringing the movable body 3 and the first fixed electrode 24 close to each other to a limit at which the sticking does not occur. Therefore, by making the angle θ formed by the first virtual straight line VL1 and the X axis sufficiently small, for example, 0.7° or less and making the first virtual straight line VL1 and the second virtual straight line VL2 as parallel to each other as possible, it is possible to sufficiently increase the sensitivity of the physical quantity sensor 1 while preventing sticking.

Next, a method of manufacturing the physical quantity sensor 1 according to the present embodiment will be described. The physical quantity sensor 1 according to the present embodiment can be manufactured by a manufacturing method including a substrate forming step, a fixed electrode forming step, a substrate bonding step, a movable body forming step, and a sealing step. In the substrate forming step, for example, a glass substrate is patterned by a photolithography step and an etching step to form the substrate 2 on which the mount portions 22a and 22b, the stoppers 11 and 12, and the like for supporting the movable body 3 are formed. In the fixed electrode forming step, a conductive film is formed on the substrate 2, and the conductive film is patterned by the photolithography step and the etching step to form fixed electrodes such as the first fixed electrode 24 and the second fixed electrode 25. In the substrate bonding step, the substrate 2 and the silicon substrate are bonded by anodic bonding or the like. In the movable body forming step, the movable body 3 is formed by thinning the silicon substrate to a predetermined thickness and patterning the silicon substrate by the photolithography step and the etching step. In this case, a Bosch process or the like, which is a deep etching technique, is used. In the sealing step, the lid 5 is bonded to the substrate 2, and the movable body 3 is stored in a space formed by the substrate 2 and the lid 5.

The manufacturing method of the physical quantity sensor 1 in the present embodiment is not limited to the manufacturing method as described above, and various manufacturing methods such as a manufacturing method using a sacrificial layer, for example, can be adopted. In the manufacturing method using the sacrificial layer, the silicon substrate on which the sacrificial layer is formed and the substrate 2 which is a support substrate are bonded to each other via the sacrificial layer, and a cavity in which the movable body 3 is swingable is formed in the sacrificial layer. Specifically, after the movable body 3 is formed on the silicon substrate, a cavity is formed by etching and removing a sacrificial layer sandwiched between the silicon substrate and the substrate 2, and the movable body 3 is released from the substrate 2. In the present embodiment, the physical quantity sensor 1 including the substrate 2 and the movable body 3 may be formed by such a manufacturing method.

The step on the lower surface of the movable body 3 can be formed by, for example, the following manufacturing process. For example, a hard mask of SiO₂ or the like is formed on the back surface side of a silicon substrate which is the back surface of the movable body 3 which is a structure. Then, a pattern in which a step forming portion is opened by the photolithography step is formed by the hard mask. Then, a step having a desired height is formed by a dry etching step or a wet etching step. In the case of forming the plurality of steps, the steps may be formed by repeating the above-described manufacturing step, or by performing the etching step a plurality of times instead of once so as to obtain a step having a desired height.

Alternatively, instead of forming the steps by processing the silicon substrate itself which is the movable body 3, as shown in FIG. 7, steps 93 and 94 corresponding to the ends EA1 and EA2 of FIGS. 2 to 4 may be formed by forming thin films 91 and 92 such as a metal film or an insulating film on the lower surface side which is the back surface side of the movable body 3.

### 2. Second Embodiment

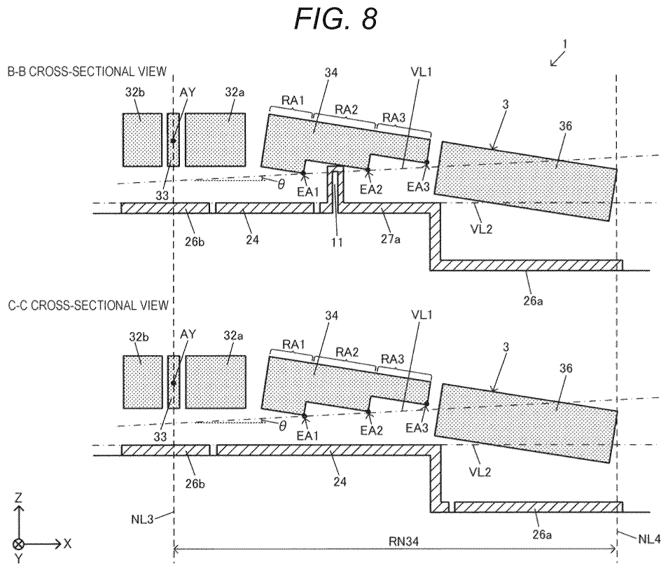

FIG. 8 is an illustrative diagram of the physical quantity sensor 1 according to a second embodiment. Here, only differences from the first embodiment will be described. As shown in FIG. 8, in a cross-sectional view from a Y-axis direction, a straight line intersecting with a rotation axis AY and extending along a Z axis is set as a third normal line NL3. A straight line intersecting an end of the movable body 3 and extending along the Z axis is set as a fourth normal line NL4. In FIG. 8, the end of the movable body 3 is an end on the positive side in an X-axis direction, and is an end of the torque generator 36. As shown in FIG. 8, in a region RN34 between the third normal line NL3 and the fourth normal line NL4, the first virtual straight line VL1 and the second virtual straight line VL2 do not intersect with each other.

In this manner, in the region RN34 in FIG. 8, which is wider than the region RN12 in FIG. 5, since the first virtual straight line VL1 and the second virtual straight line VL2 do not intersect with each other, compared with the first embodiment of FIG. 5, it becomes possible to ensure that the first virtual straight line VL1 and the second virtual straight line VL2 are closer to parallel. Therefore, when the movable body 3 is maximally displaced, a distance between the lower surface of the movable body 3 and the first fixed electrode 24 can be made larger than that in the first embodiment in FIG. 5. As a result, not only contact between the movable body 3 and the first fixed electrode 24, but also the sticking caused by an electrostatic force generated between the movable body 3 and the first fixed electrode 24 having different potentials can be further prevented, so that it is possible to provide the physical quantity sensor 1 having higher reliability.

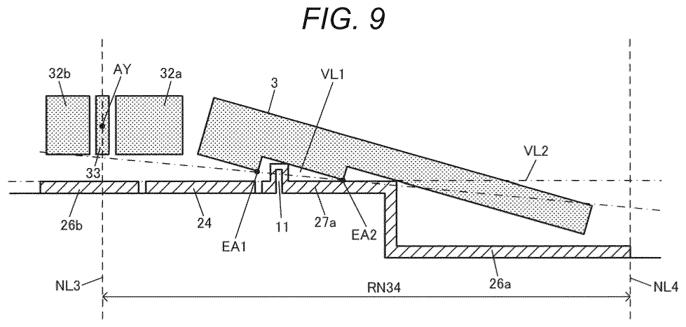

For example, FIG. 9 is an example in which the first virtual straight line VL1 and the second virtual straight line VL2 intersect with each other in the region RN34. As shown in FIG. 9, when the first virtual straight line VL1 and the second virtual straight line VL2 intersect with each other in the region RN34, for example, a problem occurs in which the end EA2 on the lower surface of the movable body 3 comes into contact with the first fixed electrode 24. If such a problem occurs, the physical quantity sensor 1 does not normally operate. In this regard, in the present embodiment, as shown in FIG. 8, even in a state where the movable body 3 is maximally displaced, the first virtual straight line VL1 and the second virtual straight line VL2 do not intersect with each other in the region RN34.

### 3. Third Embodiment

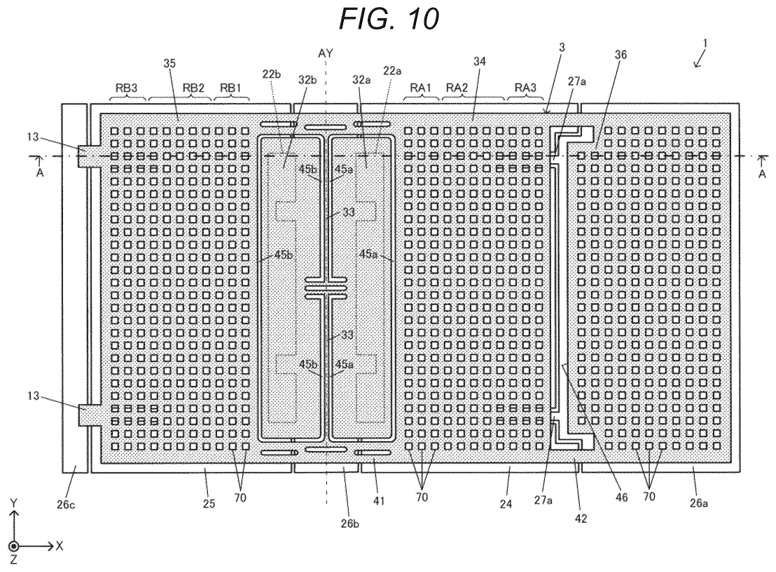

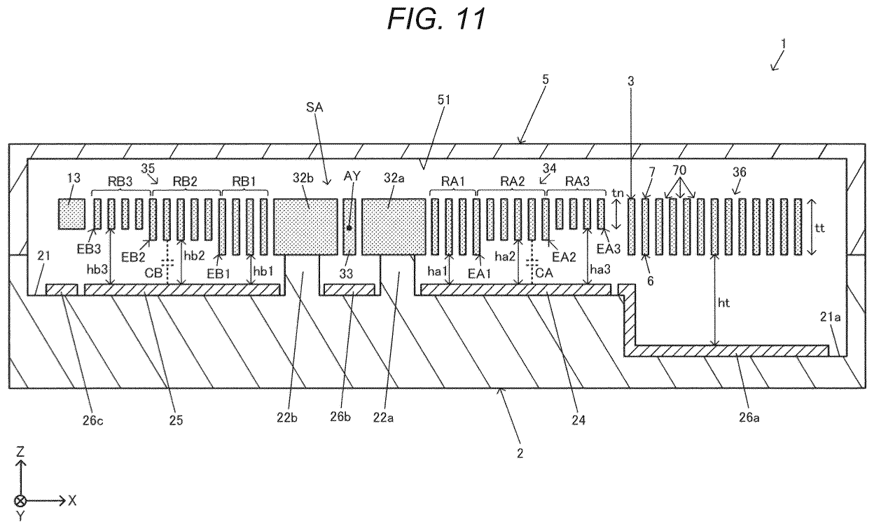

FIG. 10 is a plan view of the physical quantity sensor 1 according to the third embodiment. FIG. 11 is a cross-sectional view taken along line A-A of FIG. 10. Here, only differences from the first embodiment will be described. In the first embodiment, as shown in FIG. 3, the stoppers 11 and 12 implemented by protrusions are provided on the substrate 2. On the other hand, in the third embodiment in FIGS. 10 and 11, the movable body 3 is provided with a stopper 13. Specifically, the stopper 13 is implemented by a protrusion having a convex shape protruding along, for example, an X-axis direction from a side surface of an end of the movable body 3. Specifically, in FIGS. 10 and 11, the stopper 13 is implemented by two protrusions protruding to a negative side in the X-axis direction from the side surface of the end of the second mass portion 35 of the movable body 3. As shown in FIG. 11, the dummy electrode 26c is provided immediately below the stopper 13 on the negative side in the Z-axis direction. When the stopper 13 comes into contact with the dummy electrode 26c, the rotation of the movable body 3 about the rotation axis AY is restricted. Since the dummy electrode 26c has the same potential as that of the movable body 3, a short circuit at the time of contact is prevented.

The stopper 13 formed by the protrusion on the side surface of the end of the movable body 3 can be formed at the same time as patterning of the movable body 3. Therefore, as compared with the stoppers 11 and 12 formed by the protrusions provided on the substrate 2 as in the first embodiment, the manufacturing process can be simplified, and cost reduction and the like can be implemented.

Although not shown, in the case where a length of the movable body 3 in the X-axis direction, which is a longitudinal direction of the movable body 3, is symmetrical with respect to the rotation axis AY, or the like, stoppers serving as the protrusions may be provided on the side surfaces of the ends on both sides of the movable body 3. For example, the protrusion protruding to the negative side in the X-axis direction may be provided on the side surface of the end of the movable body 3 on the negative side in the X-axis direction, and the protrusion protruding to the positive side in the X-axis direction may be provided on the side surface of the end of the movable body 3 on the positive side in the X-axis direction. In FIGS. 10 and 11, the protrusion is provided on the side surface of the movable body 3, whereas the protrusion serving as the stopper may be provided on the surface of the movable body 3 on the substrate 2 side. Alternatively, the protrusion serving as the stopper may be provided on the surface of the lid 5 on the movable body 3 side.

### 4. Fourth Embodiment

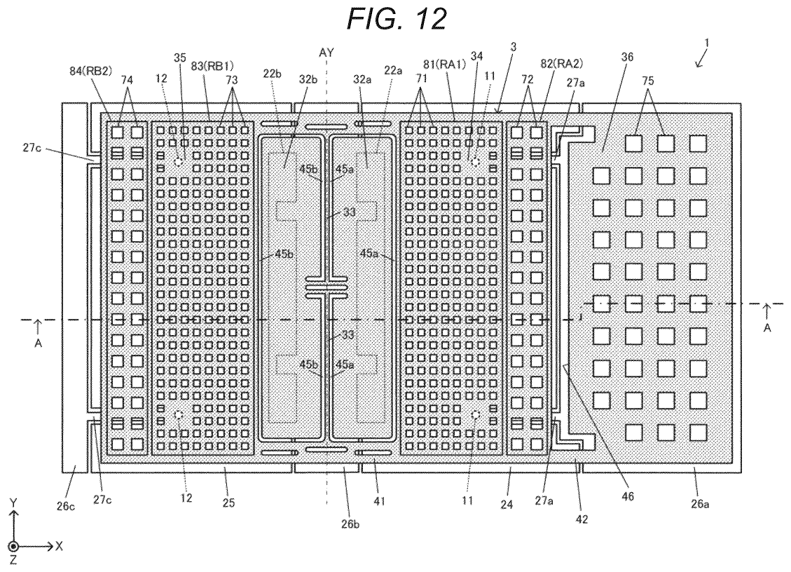

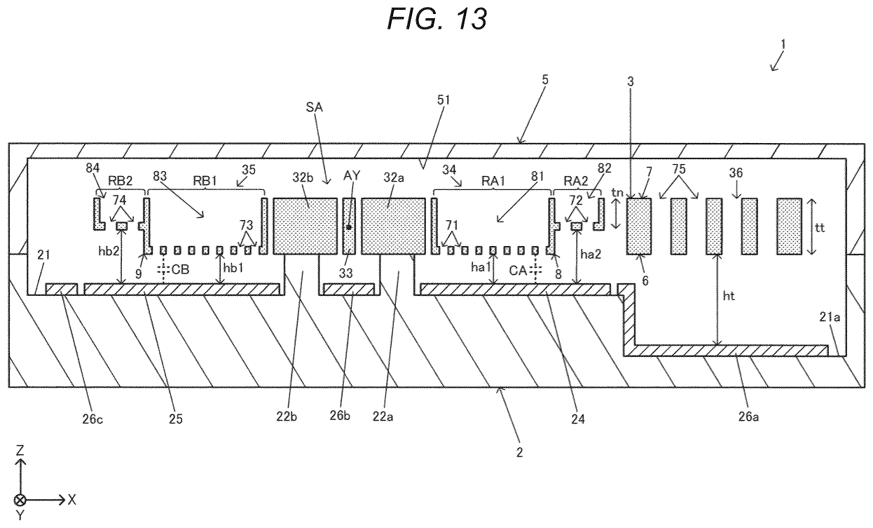

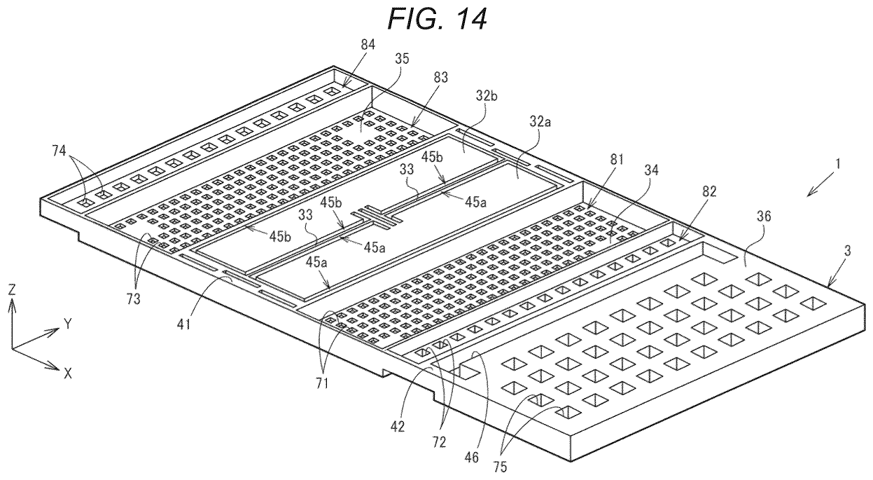

FIG. 12 is a plan view of the physical quantity sensor 1 according to a fourth embodiment. FIG. 13 is a cross-sectional view taken along line A-A of FIG. 12. FIG. 14 is a perspective view of the physical quantity sensor 1 according to the fourth embodiment. Here, only differences from the first embodiment will be described.

In the fourth embodiment, a first through hole group 71 is provided in the region RA1 that is a first region. A second through hole group 72 is provided in an i-th region among the regions RA1 to RAn which are a first region to the n-th region. Here, i is an integer satisfying 1<i≤ n. FIGS. 12 to 14 show an example of a case where n=2 and i=2. The second through hole group 72 is provided in the region RA2 which is the i-th region. n is not limited to 2, and n may be equal to or greater than 3. For example, the regions RA1 to RA3 may be provided in the first mass portion 34. In this case, the second through hole group 72 provided in the i-th region is a through hole group provided in the region RA2 or the region RA3.

As shown in FIGS. 13 and 14, the depth of the through holes of the first through hole group 71 and the second through hole group 72 in the Z-axis direction is smaller than a maximum thickness of the movable body 3 in the Z-axis direction. By reducing the depths of the through holes of the first through hole group 71 and the second through hole group 72 in this way, it is possible to reduce in-hole damping or the like in the through holes, and it is possible to implement low damping of the physical quantity sensor 1. Accordingly, it is possible to provide the physical quantity sensor 1 that can achieve both higher sensitivity and low damping.

Here, the through hole of the first through hole group 71 is a through hole constituting the first through hole group 71. The through hole of the second through hole group 72 is a through hole constituting the second through hole group 72. The depth of the through hole in the Z-axis direction is the length of the through hole in the Z-axis direction, and can also be referred to as the thickness of the through hole. The maximum thickness of the movable body 3 is the thickness of the movable body 3 at a position where the thickness in the Z-axis direction is the largest in the movable body 3. For example, when the movable body 3 is formed by patterning a silicon substrate by etching or the like, the maximum thickness of the movable body 3 can be said to be, for example, the thickness of the silicon substrate before patterning. Specifically, the maximum thickness of the movable body 3 is the thickness in the Z-axis direction of at least one of the fixing portions 32a and 32b and the support beam 33. For example, the maximum thickness of the movable body 3 is the thickness of the fixing portions 32a and 32b in the Z-axis direction or the thickness of the support beam 33 in the Z-axis direction. Alternatively, when the thicknesses of the fixing portions 32a and 32b and the support beam 33 are equal to each other, the maximum thickness of the movable body 3 is the thickness of the fixing portions 32a and 32b and the support beam 33 in the Z-axis direction. In this way, the depth in the Z-axis direction of the through holes of the first through hole group 71 and the second through hole group 72 can be made smaller than the thickness in the Z-axis direction of at least one of the fixing portions 32a and 32b and the support beam 33. Accordingly, the in-hole damping or the like of the through hole can be reduced, and the physical quantity sensor 1 can be appropriately operated in a wider frequency range.

In FIGS. 12 to 14, a third through hole group 73 is provided in the region RB1. A fourth through hole group 74 is provided in the region RB2. The depths of the through holes of the third through hole group 73 and the fourth through hole group 74 in the Z-axis direction are smaller than the maximum thickness of the movable body 3 in the Z-axis direction. By reducing the depths of the through holes of the third through hole group 73 and the fourth through hole group 74 in this way, it is possible to reduce the in-hole damping and the like of the through holes, and it is possible to implement low damping of the physical quantity sensor 1. A fifth through hole group 75 is provided in the torque generator 36 of the movable body 3.

In the fourth embodiment, similarly to the first embodiment, a step 8 for making the gap distance ha1 smaller than the gap distance ha2 is provided on the first surface 6 which is the lower surface of the first mass portion 34. The step 8 corresponds to the end EA1 in FIG. 2. That is, the first mass portion 34 faces the first fixed electrode 24 provided on the substrate 2, whereas the step 8 is provided on the first surface 6 which is the surface of the first mass portion 34 on the substrate 2 side so that the gap distance ha1 in the region RA1 is smaller than the gap distance ha2 in the region RA2. By providing the step 8 and reducing the gap distance ha1 in this manner, it is possible to implement a narrow gap in the region RA1 which is a region on the side close to the rotation axis AY among the plurality of regions of the first mass portion 34, and thus it is possible to implement high sensitivity of the physical quantity sensor 1.

Similarly, the first surface 6, which is the lower surface of the second mass portion 35, is provided with a step 9 for making the gap distance hb1 smaller than the gap distance hb2. The step 9 corresponds to the end EB1 in FIG. 2. That is, the second mass portion 35 faces the second fixed electrode 25 provided on the substrate 2, whereas the step 9 is provided on the first surface 6 which is the surface of the second mass portion 35 on the substrate 2 side so that the gap distance hb1 in the region RB1 is smaller than the gap distance hb2 in the region RB2. By providing the step 9 and reducing the gap distance hb1 in this manner, it is possible to implement a narrow gap of the region RB1 which is a region on the side close to the rotation axis AY among the plurality of regions of the second mass portion 35, and thus it is possible to implement high sensitivity of the physical quantity sensor 1.

As described above, in the physical quantity sensor 1 according to the fourth embodiment, a plurality of inter-electrode gaps are formed by providing the steps 8 and 9 which are ends with respect to the first surface 6 which is the lower surface side of the movable body 3, and the depth of the through hole of the movable body 3 is reduced, thereby implementing both high sensitivity and low damping.

In order to implement the high sensitivity, it is desirable to make the width in the X-axis direction of the support beam 33, which is a torsion spring, as small as possible. However, when the width of the support beam 33 is reduced as described above, a problem such as damage to the support beam may occur. In this regard, in the present embodiment, the fixing portions 32a and 32b disposed on both sides of the support beam are provided over the width direction of the movable body 3 in the Y-axis direction. The fixing portion 32a is a first fixing portion. The fixing portion 32b is a second fixing portion. The fixing portions 32a and 32b are fixed to the mount portions 22a and 22b of the substrate 2. For example, the width of the movable body 3 in the Y-axis direction is represented by WM. In this case, the fixing portions 32a and 32b are provided on both sides of the support beam 33 so that a width WF in the Y-axis direction, which is a long-side direction of the fixing portions 32a and 32b, is longer than, for example, WM/2. By providing the fixing portions 32a and 32b over a wide distance on both sides of the support beam 33 in this way, even when the physical quantity sensor 1 receives an impact, it is possible to prevent damage or the like to the support beam 33 due to the impact. For example, in a position immediately close to the rotation axis AY, displacement hardly occurs when the acceleration is applied. Therefore, even if an electrode is formed in the position immediately close to the rotation axis AY, the electrode hardly contributes to sensitivity. Therefore, in the present embodiment, the fixing portions 32a and 32b are provided at positions close to the rotation axis AY which does not contribute to the sensitivity in this way to prevent the support beam 33 from being damaged or the like, thereby achieving effective use of a dead space.

As shown in FIGS. 12 to 14, the opening area of the through holes of the second through hole group 72 is larger than the opening area of the through holes of the first through hole group 71. Similarly, the opening area of the through holes of the fourth through hole group 74 is larger than the opening area of the through holes of the third through hole group 73. The opening area of the through holes of the first through hole group 71 is equal to the opening area of the through holes of the third through hole group 73. The opening area of the through holes of the second through hole group 72 is equal to the opening area of the through holes of the fourth through hole group 74. Here, the opening area of the through holes of the through hole group is the opening area of one through hole constituting the through hole group. In this way, by making the opening areas of the through holes of the second through hole group 72 and the fourth through hole group 74 which are far from the rotation axis AY larger than the opening areas of the through holes of the first through hole group 71 and the third through hole group 73 which are close to the rotation axis AY, it is possible to satisfy a dimension condition of the through holes which can implement the low damping of the movable body 3, and it is possible to implement the low damping of the physical quantity sensor 1.

Further, the opening area of the through holes of the fifth through hole group 75 provided in the region of the torque generator 36 is larger than the opening area of the through holes of the first through hole group 71 and the second through hole group 72. Similarly, the opening area of the through holes of the fifth through hole group 75 is larger than the opening areas of the through holes of the third through hole group 73 and the fourth through hole group 74. In this way, by increasing the opening area of the through hole in the torque generator 36 which is farther from the rotation axis AY than the first mass portion 34 and the second mass portion 35, it is possible to satisfy the dimension condition of the through hole which can implement the low damping of the movable body 3, and it is possible to implement further low damping of the physical quantity sensor 1.

As the dimension of the through hole, a value in the vicinity of a minimum condition of damping determined by parameters of the gap distance, the depth of the through hole, and a ratio of dimension of the through hole/distance between hole ends can be adopted. Specifically, square through holes having different sizes are provided in each region. For example, the opening area of the through holes in the region RA1 and the region RB1 close to the rotation axis AY is about 5 μm×5 μm as an example. The opening area of the through holes in the region RA2 and the region RB2 far from the rotation axis AY is about 8 μm×8 μm as an example. The opening area of the through hole in the torque generator 36 further away from the rotation axis AY is, for example, about 20 μm×20 μm.

The depth of the through holes of the first through hole group 71 and the second through hole group 72 is less than 50% of the maximum thickness of the movable body 3 in the Z-axis direction. For example, the depth of the through holes is less than 50% of the thickness of the fixing portions 32a and 32b or the support beam 33, which is the maximum thickness of the movable body 3. Similarly, the depths of the through holes of the third through hole group 73 and the fourth through hole group 74 are also less than 50% of the maximum thickness of the movable body 3 in the Z-axis direction. By setting the depth of the through hole to be less than a half of the maximum thickness of the movable body 3 in this way, the in-hole damping of the through hole can be made sufficiently small compared to the case where the depth of the through hole is equal to the maximum thickness of the movable body 3, and low damping can be implemented. More preferably, the depth of the through holes such as the first through hole group 71 and the second through hole group 72 is less than 17% of the maximum thickness of the movable body 3. Accordingly, further low damping can be implemented.

As shown in FIGS. 12 to 14, in the present embodiment, the second surface 7 of the movable body 3 is provided with a first recess 81 in which the first through hole group 71 is disposed on the bottom surface, in the region RA1. That is, the second surface 7, which is the surface of the first mass portion 34 on the lid 5 side, is provided with the first recess 81 recessed to the negative side in the Z-axis direction in the region RA1. As shown in FIG. 14, in the first recess 81, a plurality of wall portions, for example, four wall portions, are provided so as to surround an arrangement region of the first through hole group 71, and rigidity in the region RA1 is ensured by the wall portions. That is, as described above, the depth of the first through hole group 71 is smaller than the maximum thickness of the movable body 3 for the low damping. For this reason, the thickness of the movable body 3 in the arrangement region of the first through hole group 71 becomes thin, and the rigidity becomes weak, so that the risk of damage may be increased. In this regard, in FIGS. 12 to 14, by forming the region RA1 in a recessed shape, the rigidity of the movable body 3 in the region RA1 is increased by the wall portion which is an edge of the first recess 81, and it is possible to avoid the risk of damage or the like.

Similarly, in the second surface 7 of the movable body 3, a third recess 83 in which the third through hole group 73 is disposed on the bottom surface is provided in the region RB1. As shown in FIG. 14, in the third recess 83, a plurality of wall portions are provided so as to surround the arrangement region of the third through hole group 73, and the rigidity in the region RB1 is ensured by the wall portions.

As shown in FIGS. 12 to 14, the second surface 7 of the movable body 3 is provided with a second recess 82 in which the second through hole group 72 is disposed on the bottom surface thereof in the region RA2. That is, the second surface 7, which is the surface of the first mass portion 34 on the lid 5 side, is provided with the second recess 82 recessed to the negative side in the Z-axis direction in the region RA2. As shown in FIG. 14, in the second recess 82, a plurality of wall portions, for example, four wall portions, are provided so as to surround the arrangement region of the second through hole group 72, and the rigidity in the region RA2 is ensured by the wall portions. Similarly, in the second surface 7 of the movable body 3, a fourth recess 84 in which the fourth through hole group 74 is disposed on the bottom surface is provided in the region RB2. As shown in FIG. 14, in the fourth recess 84, a plurality of wall portions are provided so as to surround the arrangement region of the fourth through hole group 74, and the rigidity in the region RB2 is ensured by the wall portions.

The depths of the second recess 82 and the fourth recess 84 are shallower than the depths of the first recess 81 and the third recess 83. In this way, the first recess 81, the second recess 82, the third recess 83, and the fourth recess 84 can be formed in the second surface 7 of the movable body 3 while the gap distances ha1 and hb1 in the regions RA1 and RB1 are made smaller than the gap distances ha2 and hb2 in the regions RA2 and RB2.

Further, in the present embodiment, the thickness of the through hole, which is the depth of the through hole, is reduced by forming the first recess 81 to the fourth recess 84 in the movable body 3. At the same time, the thickness of the region between the ends of the through holes, that is, between the adjacent through holes is also reduced. Then, considering that, for example, the lower stoppers 11 and 12 are in contact with the region, it is disadvantageous in terms of the strength of the structure. Therefore, it is desirable to increase the thickness of the movable body 3 in the region where the stoppers 11 and 12 are in contact with each other. For example, when the stopper 11 is provided in the region RA1 in the plan view in the Z-axis direction, the thickness of the movable body 3 is increased at least in a region in contact with the stopper 11 in the region RA1. When the stopper 12 is provided in the region RB1 in the plan view in the Z-axis direction, the thickness of the movable body 3 is increased at least in a region in contact with the stopper 12 in the region RB1.

Next, the design of the through hole will be specifically described. The through hole is provided to control the damping of the gas when the movable body 3 swings. The damping is constituted by in-hole damping of the gas passing through the through hole and squeeze film damping between the movable body 3 and the substrate 2.

The larger the through hole is, the more easily the gas passes through the through hole, so that the in-hole damping can be reduced. As occupancy rate of the through holes is increased, facing area between the movable body 3 and the substrate 2 is reduced, and thus the squeeze film damping can be reduced. However, when the occupancy rate of the through hole is increased, the facing area between the movable body 3 and the first fixed electrode 24 and the second fixed electrode 25 is reduced, and the mass of the torque generator 36 is reduced. Therefore, the sensitivity of acceleration detection is reduced. On the contrary, as the through hole is made smaller, that is, as the occupancy rate is made lower, the facing area between the movable body 3 and the first fixed electrode 24 and the second fixed electrode 25 is increased, and the mass of the torque generator 36 is increased. Therefore, the sensitivity of acceleration detection is improved, whereas the damping is increased. As described above, since the detection sensitivity and the damping are in a trade-off relationship, it is extremely difficult to achieve both of the detection sensitivity and the damping.

In order to solve such a problem, in the present embodiment, the design of the through hole is devised to achieve both high sensitivity and low damping. The sensitivity of the detection of the physical quantity sensor 1 is proportional to (A) 1/h² when a gap distance which is a separation distance between the movable body 3 and the first fixed electrode 24 and the second fixed electrode 25 is h, (B) a facing area between the movable body 3 and the first fixed electrode 24 and the second fixed electrode 25, (C) a spring rigidity of the support beam 33, and (D) a mass of the torque generator 36. In the physical quantity sensor 1, first, in a state where the damping is ignored, the facing area, the gap distance, and the like with respect to the first fixed electrode 24 and the second fixed electrode 25, which are necessary for obtaining target sensitivity, are determined. In other words, the occupancy rate of the through holes is determined. Accordingly, the electrostatic capacitances Ca and Cb of necessary sizes are formed, and the physical quantity sensor 1 can obtain sufficient sensitivity.

The occupancy rate of the plurality of through holes in the first mass portion 34 and the second mass portion 35 is not particularly limited. For example, the occupancy rate is preferably 75% or more, more preferably 78% or more, and still more preferably 82% or more. Accordingly, it is easy to achieve both high sensitivity and low damping.

As described above, after the occupancy rate of the through holes is determined, for example, the damping is designed for each of the regions RA1 and RA2. As a new technical idea of minimizing the damping without changing the sensitivity, in the physical quantity sensor 1, a plurality of through holes are designed so that a difference between the in-hole damping and the squeeze film damping is as small as possible, preferably so that the in-hole damping and the squeeze film damping are equal to each other. In this way, by making the difference between the in-hole damping and the squeeze film damping as small as possible, it is possible to reduce the damping. When the in-hole damping and the squeeze film damping are equal to each other, the damping is minimized. Accordingly, it is possible to effectively reduce the damping while maintaining the sensitivity at a sufficiently high level.

Since the method of the damping design in each region is the same as each other, the damping design in the region RA1 will be representatively described below, and the description of the damping design in other regions will be omitted.

The length in the Z-axis direction of the through hole disposed in the region RA1 is set as H (μm). A half of the length in the Y-axis direction of the region RA1 of the first mass portion 34 is set as a (μm). The length in the X-axis direction of the region RA1 of the first mass portion 34 is set as L (μm). The length in the Z-axis direction, which is the gap distance in the gap of the region RA1, is set as h (μm). The length of one side of the through hole disposed in the region RA1 is set as S0 (μm). A distance between the ends of the adjacent through holes is set as S1 (μm). Viscosity resistance, which is a viscosity coefficient of the gas in the gap of the region RA1, that is, the gas filled in the storage space SA, is set as u (kg/ms). In this case, when the damping occurring in the region RA1 is set as C, C is expressed by the following Formula (1). When an interval between the through holes adjacent to each other in the X-axis direction and an interval between the through holes adjacent to each other in the Y-axis direction are different from each other, S1 can be an average value thereof.

$$C = 2 aL \frac{8 μ H}{{β}^{2} {r}_{0}^{2}} ( 1 + \frac{3 {r}_{0}^{4} K ( β )}{16 H {h}^{3}} ) [ 1 - \frac{l}{a} tanh ( \frac{a}{l} ) ] \qquad ( 1 )$$

Parameters used in the above Formula (1) is expressed by the following Formulas (2) to (8).

$${H}_{eff} = H + \frac{3 π {r}_{0}}{8} \qquad ( 2 )$$

$$l = \sqrt{\frac{2 {h}^{3} {H}_{eff} η ( β )}{3 {β}^{2} {r}_{0}^{2}}} \qquad ( 3 )$$

$$η ( β ) = 1 + \frac{3 {r}_{0}^{4} K ( β )}{16 {Hh}^{3}} \qquad ( 4 )$$

$$K ( β ) = 4 {β}^{2} - {β}^{4} - 4 ln β - 3 \qquad ( 5 )$$

$$β = \frac{{r}_{0}}{{r}_{c}} \qquad ( 6 )$$

$${r}_{c} = \frac{S 0 + S 1}{\sqrt{π}} \qquad ( 7 )$$

$${r}_{0} = 0.547 \times S 0 \qquad ( 8 )$$

Here, an in-hole damping component included in the above Formula (1) is expressed by the following Formula (9). A squeeze film damping component is expressed by the following Formula (10).

$$2 a L \frac{8 μ H}{{β}^{2} {r}_{0}^{2}} [ 1 - \frac{l}{a} tanh ( \frac{a}{l} ) ] \qquad ( 9 )$$

$$2 aL \frac{8 μ H}{{β}^{2} {r}_{0}^{2}} ( \frac{3 {r}_{0}^{4} K ( β )}{16 H {h}^{3}} ) [ 1 - \frac{l}{a} tanh ( \frac{a}{l} ) ] \qquad ( 10 )$$

Therefore, the damping C is minimized by using the dimensions of H, h, S0, and S1 in which the above Formula (9) and the above Formula (10) are equal to each other, that is, the following Formula (11) is satisfied. That is, the following Formula (11) is a conditional expression that minimizes the damping.

$$\frac{3 {r}_{0}^{4} K ( β )}{16 H {h}^{3}} = 1 \qquad ( 11 )$$

Here, the length S0 on one side of the through hole satisfying the above Formula (11) is set as S0min. The interval S1 between the adjacent through holes is set as S1min. A minimum value of the damping C, which is the damping C when the S0min and S1min are substituted into the above Formula (1), is set as Cmin. Depending on the accuracy required for the physical quantity sensor 1, when the ranges of S0 and S1 when H and h are constant satisfy the following Formula (12), the damping can be sufficiently reduced. That is, if the damping is within the minimum value Cmin+50% of the damping, the damping can be sufficiently reduced. Therefore, the sensitivity of detection in a desired frequency band can be maintained, and noise can be reduced.

$$C \leq 1.5 \times C min \qquad ( 12 )$$

It is preferable that the following Formula (13) is satisfied, it is more preferable that the following Formula (14) is satisfied, and it is still more preferable that the following Formula (15) is satisfied. Accordingly, the above-described effects can be more remarkably exhibited.

$$C \leq 1.4 \times C min \qquad ( 13 )$$

$$C \leq 1.3 \times C min \qquad ( 14 )$$

$$C \leq 1.2 \times C min \qquad ( 15 )$$

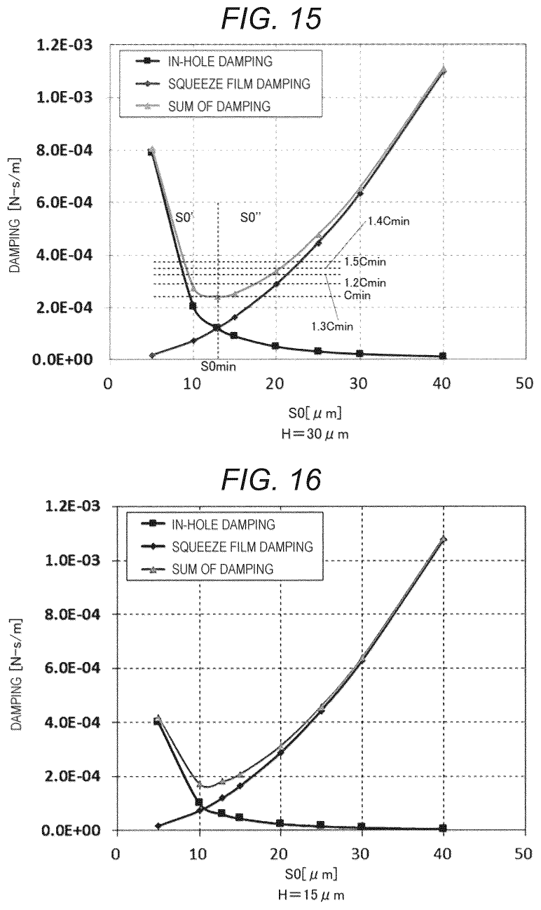

FIG. 15 is a graph showing a relationship between the length S0 on one side of the through hole and the damping. Here, H=30 μm, h=2.3 μm, a=217.5 μm, and L=785 μm. A S1/S0 ratio is set to 1 so that the sensitivity is constant. This indicates that an opening ratio does not change even when a magnitude of S0 is changed. That is, by setting the S1/S0 ratio to 1, even if the magnitude of S0 is changed, the opening ratio does not change and the facing area does not change, so that the formed electrostatic capacitance does not change and the sensitivity is maintained. Therefore, there is S0 at which the damping is minimized while the sensitivity is maintained. The opening ratio can be said to be, for example, a ratio of a sum of the opening areas of the plurality of through holes disposed in the region to the area of the region.

From the graph in FIG. 15, it can be seen that the damping in the above Formula (1) can be separated into the in-hole damping in the above Formula (9) and the squeeze film damping in the above Formula (10), the in-hole damping is dominant in a region where S0 is smaller than S0min, and the squeeze film damping is dominant in a region where S0 is larger than S0min. S0 satisfying the above Formula (12) is, as shown in FIG. 15, a range from S0′ on the side smaller than S0min to S0″ on the side larger than S0min. Compared to the range from S0min to S0″, the range from S0min to S0′ requires dimensional accuracy since the change in damping with respect to dimensional variation of S0 is large. Therefore, S0 is desirably adopted in the range from S0min to S0″ in which the dimensional accuracy can be relaxed. The same applies to the case where the above Formulas (13) to (15) are satisfied.

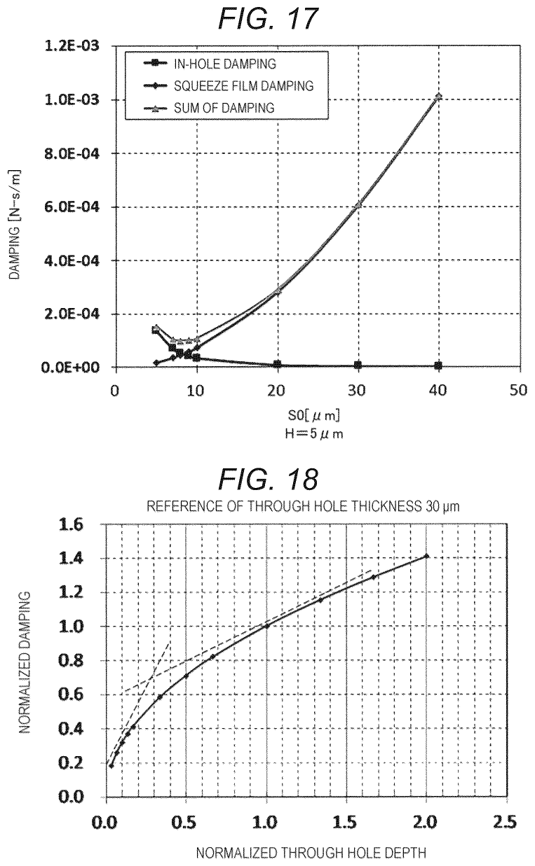

FIG. 15 is a graph showing the relationship between S0 and damping when the depth of the through hole, that is, the length in the Z direction is H=30 μm. On the other hand, FIGS. 16 and 17 are graphs showing the relationship between S0 and damping when H=15 μm and H=5 μm, respectively. As described above, FIGS. 15, 16, and 17 show a tendency of damping when the dimensions other than the depth of the through hole are the same and H which is the depth of the through hole is 30 μm, 15 μm, and 5 μm, respectively. As described above, it can be seen that, as the depth of the through hole is reduced, the squeeze film damping is not substantially changed, but the in-hole damping is reduced, and as a result, the minimum value of the overall damping is further reduced. In the present embodiment, since the depth of the through hole is set to be sufficiently smaller than the maximum thickness of the movable body 3, for example, 5 μm as shown in FIG. 17, the damping reduction effect is very large.

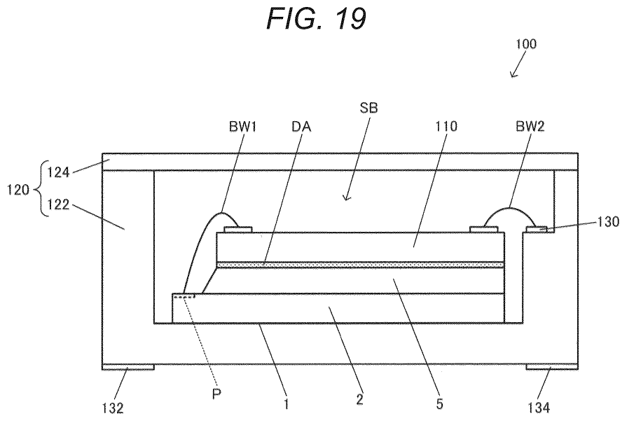

FIG. 18 is a graph showing the relationship between a normalized through hole depth and the normalized damping. Here, the normalized through hole depth is, for example, a depth of a through hole normalized with respect to a reference of a depth of the through hole when the reference of the depth of the through hole is 30 μm. As the reference of the depth of the through hole, for example, the maximum thickness of the movable body 3 can be adopted. As shown in FIG. 18, when the normalized through hole depth is 0.5, the damping can be reduced by about 30%. Therefore, for example, by setting the depth of the through hole to be less than 50% of the maximum thickness of the movable body 3 which is the reference of the depth of the through hole, the damping can be reduced by about 30%, and the low damping can be implemented. When the normalized through hole depth is 0.17, the damping can be reduced by about 60%. Therefore, for example, by setting the depth of the through hole to be less than 17% of the maximum thickness of the movable body 3, the damping can be reduced by about 60%, and the damping can be sufficiently reduced. As described above, in the present embodiment, the depth of the through holes such as the first through hole group 71 and the second through hole group 72 is preferably less than 50% of the maximum thickness of the movable body 3, and more preferably less than 17% of the maximum thickness of the movable body 3.

In the present embodiment, as shown in FIGS. 12 to 14, the opening area of the through holes of the second through hole group 72 in the region RA2 of the first mass portion 34 is larger than the opening area of the through holes of the first through hole group 71 in the region RA1. Similarly, the opening area of the through holes of the fourth through hole group 74 in the region RB2 of the second mass portion 35 is larger than the opening area of the through holes of the third through hole group 73 in the region RB1. Further, the opening area of the through holes of the fifth through hole group 75 of the torque generator 36 is larger than the opening area of the through holes of the first through hole group 71, the second through hole group 72, and the like.

For example, in the above Formula (11) which is a conditional expression for minimizing the damping, the numerator has a term of r₀⁴=(0.547×S0)⁴, and the denominator has a term of h3. Therefore, when the gap distance h between the electrodes increases, the minimum condition of the damping can be satisfied by increasing the length S0 on one side of the through hole accordingly. That is, as the gap distance h increases, S0, which is the length on one side of the through hole, is increased to increase the opening area of the through hole, thereby making it possible to bring the damping close to the minimum value.

In the present embodiment, the gap distance ha2 in the region RA2 is larger than the gap distance ha1 in the region RA1. Therefore, by making the opening area of the second through hole group 72 in the region RA2 larger than the opening area of the first through hole group 71 in the region RA1, the damping in each of the regions RA1 and RA2 can be brought close to the minimum value expressed by the above Formula (11). Similarly, the gap distance hb2 in the region RB2 is larger than the gap distance hb1 in the region RB1. Therefore, by making the opening area of the fourth through hole group 74 in the region RB2 larger than the opening area of the third through hole group 73 in the region RB1, the damping in each of the regions RB1 and RB2 can be made close to the minimum value expressed by the above Formula (11).

The gap distance ht in the region of the torque generator 36 is larger than the gap distances ha1, ha2, and the like. Therefore, by making the opening area of the fifth through hole group 75 in the region of the torque generator 36 larger than the opening areas of the first through hole group 71, the second through hole group 72, and the like, the damping in the region of the torque generator 36 can be made close to the minimum value expressed by the above Formula (11).

In FIGS. 12 to 14, the depth of the through hole is reduced by providing the second surface 7, which is the upper surface of the movable body 3, with the recess in which the through hole group is disposed on the bottom surface, whereas the present embodiment is not limited thereto. For example, the depth of the through hole may be reduced by providing the first surface 6, which is the lower surface of the movable body 3, with the recess in which the through hole group is disposed on the bottom surface. Alternatively, the depth of the through hole may be reduced by providing a recess for each of at least one through hole of the through hole group. For example, the thickness of the movable body 3 is set to be equal to the depth of the through hole in the periphery of the through hole, and the thickness of the movable body 3 is set to be larger than the depth of the through hole between the ends of the adjacent through holes. That is, the rigidity is ensured by providing a wall portion of the recess having a large thickness around the through hole. Accordingly, the strength of the movable body 3 can be increased and the rigidity can be secured without substantially increasing the damping. Further, various modifications can be made to the arrangement of the through holes in the through hole group. For example, the arrangement of the through holes may be a honeycomb arrangement having high strength.

### 5. Physical Quantity Sensor Device

Next, a physical quantity sensor device 100 according to the present embodiment will be described with reference to FIG. 19. FIG. 19 is a cross-sectional view of the physical quantity sensor device 100. The physical quantity sensor device 100 includes the physical quantity sensor 1 and an integrated circuit (IC) chip 110 as an electronic component. The IC chip 110 may be referred to as a semiconductor chip, and is a semiconductor element. The IC chip 110 is bonded to the upper surface of the lid 5 of the physical quantity sensor 1 via a die attach material DA, which is a bonding member. The IC chip 110 is electrically coupled to an electrode pad P of the physical quantity sensor 1 via a bonding wire BW1. The IC chip 110, which is a circuit device, includes, for example, a drive circuit that applies a drive voltage to the physical quantity sensor 1, a detection circuit that detects acceleration based on an output from the physical quantity sensor 1, and an output circuit that converts a signal from the detection circuit into a predetermined signal and outputs the predetermined signal as necessary. As described above, since the physical quantity device 100 according to the present embodiment includes the physical quantity sensor 1 and the IC chip 110, the effect of the physical quantity sensor 1 can be enjoyed, and the physical quantity sensor device 100 capable of implementing high accuracy and the like can be provided.

The physical quantity sensor device 100 may include a package 120 that is a container in which the physical quantity sensor 1 and the IC chip 110 are stored. The package 120 includes a base 122 and a lid 124. The physical quantity sensor 1 and the IC chip 110 are stored in a storage space SB hermetically sealed by bonding the lid 124 to the base 122. By providing such a package 120, it is possible to suitably protect the physical quantity sensor 1 and the IC chip 110 from impact, dust, heat, moisture, and the like.

The base 122 includes a plurality of internal terminals 130 disposed in the storage space SB and external terminals 132 and 134 disposed on the bottom surface. The physical quantity sensor 1 and the IC chip 110 are electrically coupled to each other via the bonding wire BW1.

The IC chip 110 and the internal terminal 130 are electrically coupled to each other via a bonding wire BW2. Further, the internal terminal 130 is electrically coupled to the external terminals 132 and 134 via an internal wiring, which is not shown, provided in the base 122. Accordingly, a sensor output signal based on the physical quantity detected by the physical quantity sensor 1 can be output to the outside.

Although the case where the electronic component provided in the physical quantity sensor device 100 is the IC chip 110 has been described above as an example, the electronic component may be a circuit element other than the IC chip 110, may be a sensor element different from the physical quantity sensor 1, or may be a display element implemented by a liquid crystal display (LCD), a light emitting diode (LED), or the like. Examples of the circuit element include passive elements such as a capacitor and a resistor, and active elements such as a transistor. The sensor element is, for example, an element that senses a physical quantity different from the physical quantity detected by the physical quantity sensor 1. Instead of providing the package 120, mold mounting may be performed.

### 6. Inertial Measurement Unit

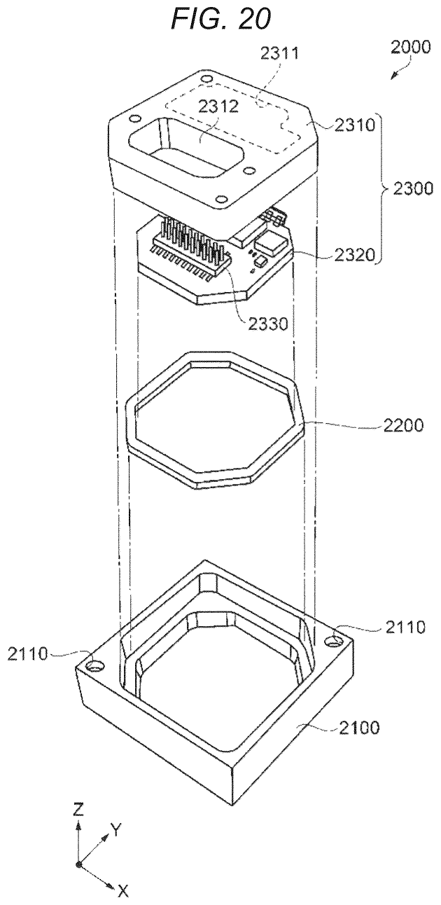

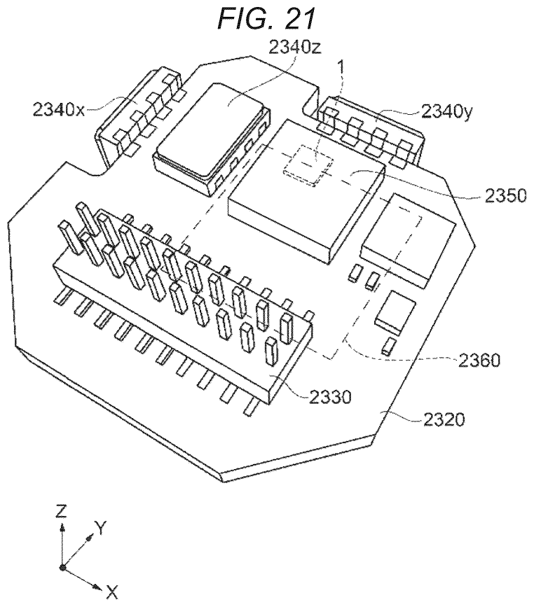

Next, an inertial measurement unit 2000 according to the present embodiment will be described with reference to FIGS. 20 and 21. An inertial measurement unit (IMU) 2000 shown in FIG. 20 is a device that detects an inertial motion amount such as a posture or a behavior of a moving body such as an automobile or a robot. The inertial measurement unit 2000 is a so-called six-axis motion sensor including an acceleration sensor that detects accelerations ax, ay, and az in directions along three axes and an angular velocity sensor that detects angular velocities ox, wy, and wz around three axes.

The inertial measurement unit 2000 is a rectangular parallelepiped having a substantially square planar shape. Screw holes 2110 as mount portions are formed in the vicinity of two vertexes located in a diagonal direction of the square. Two screws can be inserted into the screw holes 2110 at two locations to fix the inertial measurement unit 2000 to a mounted surface of a mounted body such as an automobile. It is also possible to reduce a size to a size that can be mounted on a smartphone or a digital camera, for example, by selecting a component or changing a design.

The inertial measurement unit 2000 includes an outer case 2100, a bonding member 2200, and a sensor module 2300, and has a configuration in which the sensor module 2300 is inserted inside the outer case 2100 with the bonding member 2200 sandwiched therebetween. The sensor module 2300 includes an inner case 2310 and a circuit board 2320. The inner case 2310 is formed with a recess 2311 for preventing contact with the circuit board 2320 and an opening 2312 for exposing a connector 2330 to be described later. The circuit board 2320 is bonded to the lower surface of the inner case 2310 via an adhesive.

As shown in FIG. 21, the connector 2330, an angular velocity sensor 2340z that detects an angular velocity around the Z axis, an acceleration sensor unit 2350 that detects acceleration in each axial direction of the X axis, the Y axis, and the Z axis, and the like are mounted on the upper surface of the circuit board 2320. An angular velocity sensor 2340x that detects an angular velocity around the X axis and an angular velocity sensor 2340y that detects an angular velocity around the Y axis are mounted on a side surface of the circuit board 2320.

The acceleration sensor unit 2350 includes at least the physical quantity sensor 1 for measuring the acceleration in the Z-axis direction described above, and can detect the acceleration in one axial direction or the acceleration in two axial directions or three axial directions as necessary. The angular velocity sensors 2340x, 2340y, and 2340z are not particularly limited. For example, a vibration gyro sensor using a Coriolis force can be used.

A control IC 2360 is mounted on the lower surface of the circuit board 2320. The control IC 2360 as a controller that performs control based on the detection signal output from the physical quantity sensor 1 is, for example, a micro controller unit (MCU), includes a storage including a nonvolatile memory, an A/D converter, and the like, and controls each unit of the inertial measurement unit 2000. A plurality of electronic components are mounted on the circuit board 2320.

As described above, the inertial measurement unit 2000 according to the present embodiment includes the physical quantity sensor 1 and the control IC 2360 as the controller that performs control based on the detection signal output from the physical quantity sensor 1. According to the inertial measurement unit 2000, since the acceleration sensor unit 2350 including the physical quantity sensor 1 is used, the effect of the physical quantity sensor 1 can be enjoyed, and the inertial measurement unit 2000 capable of implementing the high accuracy and the like can be provided.

As described above, the physical quantity sensor according to the present embodiment includes the substrate orthogonal to the Z axis and provided with the first fixed electrode when three axes orthogonal to one another are set as the X axis, the Y axis, and the Z axis, and the movable body including the first mass portion facing the first fixed electrode in the Z axis direction along the Z axis and provided to be swingable with respect to the substrate about the rotation axis along the Y axis. The movable body includes the first surface which is a surface on the substrate side and the second surface which is a surface on a back side with respect to the first surface, and on the first surface of the first mass portion, a step is provided between adjacent regions facing the first fixed electrode with a gap therebetween, and first to n-th regions, n being an integer of 2 or more, are provided which are disposed from the first region to the n-th region in an order close to the rotation axis. The ends of the first region to the n-th region on the side far from the rotation axis are referred to as a first end to an n-th end. In a cross-sectional view from the Y-axis direction along the Y axis, in a state where the movable body is maximally displaced around the rotation axis, among virtual straight lines passing through two ends among the first end to the n-th end, the virtual straight line having the smallest angle with respect to the X axis is set as the first virtual straight line, and the straight line along the main surface of the first fixed electrode is set as the second virtual straight line. The straight line intersecting with an end of the first fixed electrode closest to the rotation axis and extending along the Z axis is set as the first normal line. The straight line intersecting with an end of the first fixed electrode farthest from the rotation axis and extending along the Z axis is set as the second normal line. At this time, the first virtual straight line and the second virtual straight line do not intersect in a region between the first normal line and the second normal line.

According to the present embodiment, the first surface of the first mass portion of the movable body facing the first fixed electrode of the substrate is provided with the first region to the n-th region in which the step is provided between adjacent regions. By providing such a first region to an n-th region, it is possible to implement the high sensitivity of the physical quantity sensor. In the present embodiment, the first virtual straight line passing through the two ends forming the step of the first surface of the movable body and the second virtual straight line along the main surface of the first fixed electrode do not intersect with each other in the region between the first normal line corresponding to the end closest to the rotation axis of the first fixed electrode and the second normal line corresponding to the end farthest from the rotation axis of the first fixed electrode in the state where the movable body is maximally displaced. Accordingly, sticking between the movable body and the first fixed electrode can be prevented. Therefore, it is possible to provide a physical quantity sensor or the like capable of implementing both high sensitivity and reduction of sticking.

In the present embodiment, in a cross-sectional view from the Y-axis direction, when a straight line intersecting with the rotation axis and along the Z axis is set as the third normal line and a straight line intersecting with the end of the movable body and along the Z axis is set as the fourth normal line, the first virtual straight line and the second virtual straight line may not intersect each other in a region between the third normal line and the fourth normal line.

In this way, in the region between the third normal line and the fourth normal line, which is wider than the region between the first normal line and the second normal line, the first virtual straight line and the second virtual straight line do not intersect with each other. Therefore, in the state where the movable body is maximally displaced, the distance between the first surface of the movable body and the first fixed electrode can be further increased, and the occurrence of sticking can be further prevented.

In the present embodiment, the gap distance between the first region to the n-th region of the first mass portion and the first fixed electrode may increase in the order of the first region to the n-th region.

By increasing the gap distance from the first fixed electrode in the order of the first region to the n-th region in this way, it is possible to narrow the gap in the first region or the like close to the rotation axis, and it is possible to implement high sensitivity of the physical quantity sensor.

In the present embodiment, the movable body may include the torque generator for generating the rotational torque around the rotation axis. The gap distance between the torque generator and the substrate may be larger than the gap distance between the n-th region and the first fixed electrode.

In this way, it is possible to implement the reduction in damping and the expansion of the movable range of the movable body.

In the present embodiment, the movable body may include the torque generator for generating the rotational torque around the rotation axis. The thickness of the torque generator in the Z-axis direction may be larger than the thickness of the n-th region of the movable body in the Z-axis direction.

In this way, since the rotational torque in the torque generator at the time of swinging of the movable body can be further increased, higher sensitivity can be implemented.

In the present embodiment, the movable body may include the second mass portion which is provided to sandwich the rotation axis with respect to the first mass portion in the plan view from the Z-axis direction, the substrate may be provided with the second fixed electrode which faces the second mass portion, and the first fixed electrode and the second fixed electrode may be symmetrically disposed with respect to the rotation axis.

In this way, the first fixed electrode facing the first mass portion and the second fixed electrode facing the second mass portion are symmetrically disposed with respect to the rotation axis, so that the seesaw swing type physical quantity sensor can be implemented.

In the present embodiment, a stopper that restricts the rotation of the movable body about the rotation axis may be included.

By providing such a stopper, it is possible to prevent excessive proximity between the movable body and the first fixed electrode or the like.

Further, in the present embodiment, the maximum displacement state may be a state in which the rotation of the movable body is restricted by the stopper.

In this way, when the rotation of the movable body is restricted by the stopper, the first virtual straight line and the second virtual straight line do not intersect with each other in the region between the first normal line and the second normal line, and thus the sticking can be prevented while achieving high sensitivity.

In the present embodiment, the stopper may have the same potential as the movable body.

Since the stopper and the movable body have the same potential in this manner, an unnecessary electrostatic force due to a different potential does not work, so that the sticking can be further prevented.

In the present embodiment, a dummy electrode which is disposed in a region of the substrate where the first fixed electrode is not disposed and which faces the movable body and has the same potential as the movable body may be included.

In this way, the exposure of the surface of the substrate can be prevented using the dummy electrode, and the occurrence of sticking can be prevented.

In the present embodiment, the movable body may be provided with a through hole group penetrating in the Z-axis direction.

By providing the through hole group in the movable body in this way, it is possible to reduce damping of air when the movable body swings around the rotation axis.

In the present embodiment, the gap distance between the first mass portion and the first fixed electrode may be 4.5 μm or less.

By making the gap distance sufficiently small in this way, it is possible to sufficiently increase the detection sensitivity of the physical quantity sensor.

In the present embodiment, the angle between the first virtual straight line and the X axis may be 0.7º or less.

In this way, the first virtual straight line and the second virtual straight line come closer to be parallel to each other, and the movable body and the first fixed electrode come closer to each other to the limit at which sticking does not occur, so that the high sensitivity of the physical quantity sensor can be implemented.

In the present embodiment, the first through hole group may be provided in the first region, the second through hole group may be provided in an i-th region, i being an integer satisfying 1<i≤n, among the first region to the n-th region, and depths of the through holes of the first through hole group and the second through hole group in the Z-axis direction may be smaller than the maximum thickness of the movable body in the Z-axis direction.

In this way, since the depths of the through holes of the first through hole group and the second through hole group are smaller than the maximum thickness of the movable body, in-hole damping or the like of the through holes can be reduced, and low damping can be implemented.

In the present embodiment, the opening area of the through holes of the second through hole group may be larger than the opening area of the through holes of the first through hole group.

In this way, by making the opening area of the through holes of the second through hole group far from the rotation axis larger than the opening area of the through holes of the first through hole group close to the rotation axis, it is possible to satisfy the dimension condition of the through holes that can implement the low damping, and it is possible to implement the low damping of the physical quantity sensor.

The present embodiment relates to a physical quantity sensor device including the physical quantity sensor described above and the electronic component electrically coupled to the physical quantity sensor.

The present embodiment relates to the inertial measurement unit including the physical quantity sensor described above and the controller that performs control based on the detection signal output from the physical quantity sensor.

Although the present embodiment has been described in detail above, it will be easily understood by those skilled in the art that many modifications can be made without substantially departing from the novel matters and effects of the present disclosure. Therefore, all such modifications are intended to be included within the scope of the present disclosure. For example, a term cited with a different term having a broader meaning or the same meaning at least once in the present disclosure or in the drawings can be replaced with the different term in any place in the present disclosure or in the drawings. All combinations of the present embodiment and the modifications are also included in the scope of the present disclosure. The configurations, operations, and the like of the physical quantity sensor, the physical quantity sensor device, and the inertial measurement unit are not limited to those described in the present embodiment, and various modifications can be made.

What is claimed is:

1. A physical quantity sensor comprising:
three axes orthogonal to each other being defined as an X axis, a Y axis, and a Z axis;
a substrate;
a first fixed electrode and a dummy electrode provided on the substrate, the first fixed electrode and the dummy electrode extending orthogonal to the Z axis; and
a movable body provided to be swingable with respect to the substrate about a rotation axis along the Y axis, the movable body having first and second surfaces outwardly opposite to each other, the first surface facing the substrate, the movable body including:
a first mass facing the first fixed electrode along the Z axis; and
a torque generator continuously extending from the first mass and facing the dummy electrode,
wherein, on the first surface of the first mass,
a first region to an n-th region, n being an integer equal to or greater than 2, are provided so as to face the first fixed electrode with a gap therebetween, a step is provided between adjacent regions, and the first region to the n-th region are disposed in order from a closest region to the rotation axis, each cross section along an XZ plane of the first region to the n-th region being in a rectangular shape having a top mass surface and a bottom mass surface that are parallel to each other, the XZ plane extending along the X axis and the Z axis, wherein the first fixed electrode faces a plurality of regions among the first region to the n-th region, and the dummy electrode has the same potential as the movable body,
a first recess is provided on the second surface of the first region, and a first through hole group is arranged on a bottom recess surface of the first recess,
an n-th recess is provided on the second surface of the n-th region, and an n-th through hole group is arranged on a bottom recess surface of the n-th recess,
wherein an opening area of each of through holes of the n-th through hole group is larger than an opening area of each of through holes of the first through hole group, and
a depth of the n-th recess is shallower than a depth of the first recess, and
ends of the first region to the n-th region on a side far from the rotation axis are set as a first end to an n-th end,
in a cross-sectional view along the Y axis,
in a state where the movable body is maximally displaced around the rotation axis toward the substrate, a first virtual straight line having a smallest angle with the X axis passes through two ends of the first end to the n-th end,
a second virtual straight line extends along a main surface of the first fixed electrode,
a first normal line with respect to the first fixed electrode intersects with an end of the first fixed electrode closest to the rotation axis and extends along the Z axis,
a second normal line with respect to the first fixed electrode intersects with an end of the first fixed electrode farthest from the rotation axis and extends along the Z axis,
the first virtual straight line and the second virtual straight line do not intersect with each other in a region between the first normal line and the second normal line, and
the first and second virtual straight lines and the second normal line pass through the torque generator, and
a thickness along the Z axis of the first region is larger than a thickness along the Z axis of a subsequent region that is located adjacent to the first region.

2. The physical quantity sensor according to claim 1, wherein
in the cross-sectional view along the Y axis,
a third normal line with respect to the substrate intersects with the rotation axis and extends along the Z axis, and
a fourth normal line with respect to the dummy electrode intersects with an end of the torque generator of the movable body and extends along the Z axis, and
the first virtual straight line and the second virtual straight line do not intersect with each other in a region between the third normal line and the fourth normal line.

3. The physical quantity sensor according to claim 1, wherein
a gap distance between the first region to the n-th region of the first mass and the first fixed electrode increases in order from the first region to the n-th region.

4. The physical quantity sensor according to claim 1, wherein
the torque generator is configured to generate rotational torque around the rotation axis, and
a gap distance between the torque generator and the dummy electrode is larger than a gap distance between the n-th region and the first fixed electrode.

5. The physical quantity sensor according to claim 1, wherein
the torque generator is configured to generate rotational torque around the rotation axis, and
a thickness of the torque generator along the Z axis is larger than a thickness of the n-th region of the movable body along the Z axis.

6. The physical quantity sensor according to claim 1, wherein
the movable body includes a second mass provided to sandwich the rotation axis with respect to the first mass in a plan view,
a second fixed electrode is provided on the substrate and faces the second mass, and
the first fixed electrode and the second fixed electrode are symmetrically disposed with respect to the rotation axis.

7. The physical quantity sensor according to claim 1, further comprising:
a stopper that restricts rotation of the movable body about the rotation axis.

8. The physical quantity sensor according to claim 7, wherein
a maximum displacement state is a state in which the rotation of the movable body is restricted by the stopper.

9. The physical quantity sensor according to claim 7, wherein
the stopper has the same potential as the movable body.

10. The physical quantity sensor according to claim 1, wherein
the dummy electrode is disposed in a region of the substrate where the first fixed electrode is not disposed.

11. The physical quantity sensor according to claim 1, wherein
the movable body is provided with another through hole group penetrating along the Z axis.

12. The physical quantity sensor according to claim 1, wherein
a gap distance between the first mass and the first fixed electrode is 4.5 μm or less.

13. The physical quantity sensor according to claim 1, wherein
an angle formed by the first virtual straight line and the X axis is 0.7° or less.

14. The physical quantity sensor according to claim 1, wherein
the first through hole group is provided in the first region, and a second through hole group is provided in an i-th region, wherein i is an integer satisfying 1<i≤ n, among the first region to the n-th region, and
through hole depths of the first through hole group and the second through hole group along the Z axis are smaller than a maximum thickness of the movable body along the Z axis.

15. The physical quantity sensor according to claim 14, wherein
an opening area of each of through holes of the second through hole group is larger than the opening area of each of through holes of the first through hole group.

16. A physical quantity sensor device comprising:
the physical quantity sensor according to claim 1; and
an electronic component electrically coupled to the physical quantity sensor.

17. An inertial measurement unit comprising:
the physical quantity sensor according to claim 1; and
a controller configured to perform control based on a detection signal output from the physical quantity sensor.
